(19) United States
(12) Patent Application Publication
(10) Pub. No.: US 2021/0151477 A1
(43) Pub. Date: May 20, 2021

(54) IMAGING PANEL AND METHOD FOR PRODUCING SAME

(71) Applicant: Sharp Kabushiki Kaisha, Sakai City, Osaka (JP)

(72) Inventor: Katsunori MISAKI, Yonago-shi (JP)

(21) Appl. No.: 16/622,461

(22) PCT Filed: Jun. 26, 2018
(86) PCT No.: PCT/JP2018/024157

§ 371 Date: Dec. 13, 2019

(30) Foreign Application Priority Data
Jun. 27, 2017 (JP) 2017-125391

(51) Int. Cl. H01L 27/146; G01N 23/04; G01T 1/20

(52) U.S. Cl. CPC H01L 27/1461; H01L 27/14663; H01L 27/14636; H01L 27/14689; H01L 31/1055; H01L 27/14698; G01N 23/04; G01T 1/20188; H01L 27/14692

(57) ABSTRACT

Provided is an X-ray imaging panel in which off-leakage current can be suppressed, and a method for producing the same. The imaging panel includes a photoelectric conversion layer (15), a first electrode (14b), and first protection layers (105, 106). The first protection layers (105, 106) cover side surfaces of the photoelectric conversion layer (15), and have openings (105a, 106a) on an inner side with respect to an end of the photoelectric conversion layer (15), above the photoelectric conversion layer (15). The first electrode (14b) is arranged on the first protection layer (106) so as to be in contact with the photoelectric conversion layer (15) in the openings (105a, 106a).

### TECHNICAL FIELD

The present invention disclosed herein relates to an imaging panel and a method for producing the same.

### BACKGROUND ART

An X-ray imaging device that picks up an X-ray image with an imaging panel that includes a plurality of pixel portions is known. In such an X-ray imaging device, for example, p-intrinsic-n (PIN) photodiodes are used as photoelectric conversion elements, and the PIN photodiodes convert irradiated X-rays into charges. Converted charges are read out by thin film transistors (hereinafter also referred to as TFTs) that are caused to operate, the TFTs being provided in the pixel portions. The charges are read out in this way, whereby an X-ray image is obtained. JP-A-2014-078651 discloses a photoelectric conversion element array unit in which PIN photodiodes are used.

In the configuration disclosed in JP-A-2014-078651, photoelectric conversion layers of PIN photodiodes and upper electrode layers are formed by sequential etching performed from the upper layer with use of the same resist mask, into an approximately identical island pattern.

In the configuration disclosed in JP-A-2014-078651, the upper electrode layers are formed simultaneously when the photoelectric conversion layers are formed. Therefore, if the surfaces of the photoelectric conversion layers are cleaned with use of hydrofluoric acid or the like to remove organic matters and the like adhering to surfaces thereof, the upper electrode layers are exposed to hydrofluoric acid, thereby being dissolved, which results in that metal ions of the upper electrode layers adhere to the photoelectric conversion layers. In the configuration disclosed in JP-A-2014-078651, therefore, it is difficult to subject only the surfaces of the photoelectric conversion layers to the cleaning treatment with use of hydrofluoric acid or the like, and it is likely that off-leakage current would occur due to organic matters or the like.

It is an object of the present invention disclosed herein to provide an imaging panel in which off-leakage current can be suppressed.

### SUMMARY OF THE INVENTION

An imaging panel of the present invention that achieves the above-described object is an imaging panel that generates an image based on scintillation light that is obtained from X-rays transmitted through an object, and the imaging panel includes: a photoelectric conversion layer; a pair of a first electrode and a second electrode, the first electrode being provided on a side irradiated with X-rays; and a first protection layer, wherein the first protection layer covers a side surface of the photoelectric conversion layer, and overlaps with the photoelectric conversion layer on the X-ray irradiated side so as to have an opening on an inner side with respect to an end of the photoelectric conversion layer, and the first electrode is arranged so as to be in contact with the photoelectric conversion layer in the opening, and to overlap with at least a part of the first protection layer.

With the present invention, an imaging panel in which off-leakage current can be suppressed can be provided.

### BRIEF DESCRIPTION OF DRAWINGS

FIG. 1 schematically illustrates an X-ray imaging device in Embodiment 1.

FIG. 2 schematically illustrates a schematic configuration of an imaging panel illustrated in FIG. 1.

FIG. 3 is an enlarged plan view illustrating one pixel portion of the imaging panel illustrated in FIG. 2.

FIG. 4 is a cross-sectional view illustrating the pixel illustrated in FIG. 3, taken along line A-A.

FIG. 5 is an enlarged view illustrating a line frame portion illustrated in FIG. 4.

FIG. 6A is a cross-sectional view illustrating a step of forming a first insulating film on a gate insulating film and a TFT formed on a substrate, in a process for producing the imaging panel illustrated in FIG. 4.

FIG. 6B is a cross-sectional view illustrating a step of forming an opening in the first insulating film illustrated in FIG. 6A.

FIG. 6C is a cross-sectional view illustrating a step of forming a second insulating film illustrated in FIG. 4.

FIG. 6D is a cross-sectional view illustrating a step of forming an opening in the second insulating film illustrated in FIG. 6C.

FIG. 6E is a cross-sectional view illustrating a step of forming a metal film as a lower electrode illustrated in FIG. 4.

FIG. 6F is a cross-sectional view illustrating a step of forming the lower electrode illustrated in FIG. 4.

FIG. 6G is a cross-sectional view illustrating a step of forming an n-type amorphous semiconductor layer, an intrinsic amorphous semiconductor layer, and a p-type amorphous semiconductor layer as a photoelectric conversion layer illustrated in FIG. 4.

FIG. 6H is a cross-sectional view illustrating a step of forming the photoelectric conversion layer illustrated in FIG. 4.

FIG. 6I is a cross-sectional view illustrating a step of forming a third insulating film illustrated in FIG. 4.

FIG. 6J is a cross-sectional view illustrating a step of forming a fourth insulating film illustrated in FIG. 4.

FIG. 6K is a cross-sectional view illustrating a step of forming a metal film as a bias line illustrated in FIG. 4.

FIG. 6L is a cross-sectional view illustrating a step of forming the bias line illustrated in FIG. 4.

FIG. 6M is a cross-sectional view illustrating a step of forming an opening in the fourth insulating film illustrated in FIG. 4.

FIG. 6N is a cross-sectional view illustrating a step of forming an opening in the third insulating film illustrated in FIG. 4.

FIG. 6O is a cross-sectional view illustrating a step of forming a transparent conductive film as an upper electrode illustrated in FIG. 4.

FIG. 6P is a cross-sectional view illustrating a step of forming the upper electrode illustrated in FIG. 4.

FIG. 6Q is a cross-sectional view illustrating a step of forming a fifth insulating film illustrated in FIG. 4.

FIG. 6R is a cross-sectional view illustrating a step of forming a sixth insulating film illustrated in FIG. 4.

FIG. 7 is a cross-sectional view illustrating an imaging panel in Embodiment 2.

FIG. 8A is a cross-sectional view illustrating a step of forming a metal film as a bias line illustrated in FIG. 7.

FIG. 8B is a cross-sectional view illustrating a step of forming the bias line illustrated in FIG. 7.

FIG. 8C is a cross-sectional view illustrating a step of forming an opening in a third insulating film illustrated in FIG. 7.

FIG. 8D is a cross-sectional view illustrating a step of forming a transparent conductive film as an upper electrode illustrated in FIG. 7.

FIG. 8E is a cross-sectional view illustrating a step of forming the upper electrode illustrated in FIG. 7.

FIG. 8F is a cross-sectional view illustrating a step of forming a fourth insulating film illustrated in FIG. 7.

FIG. 8G is a cross-sectional view illustrating a step of forming an opening in the fourth insulating film illustrated in FIG. 7.

FIG. 8H is a cross-sectional view illustrating a step of forming a fifth insulating film illustrated in FIG. 7.

FIG. 8I is a cross-sectional view illustrating a step of forming a sixth insulating film illustrated in FIG. 7.

FIG. 9A is a cross-sectional view illustrating an imaging panel in Application Example 1 of Embodiment 2.

FIG. 9B is a cross-sectional view illustrating an imaging panel in Application Example 2 of Embodiment 2.

FIG. 10 is a cross-sectional view illustrating an imaging panel in Embodiment 3.

FIG. 11A is a cross-sectional view illustrating a step of forming an opening in a third insulating film illustrated in FIG. 10.

FIG. 11B is a cross-sectional view illustrating a step of forming a transparent conductive film as an upper electrode illustrated in FIG. 10.

FIG. 11C is a cross-sectional view illustrating a step of forming the upper electrode illustrated in FIG. 10.

FIG. 11D is a cross-sectional view illustrating a step of forming a fourth insulating film illustrated in FIG. 10.

FIG. 11E is a cross-sectional view illustrating a step of forming an opening in the fourth insulating film illustrated in FIG. 10.

FIG. 11F is a cross-sectional view illustrating a step of forming a metal film as a bias line illustrated in FIG. 10.

FIG. 11G is a cross-sectional view illustrating a step of forming a bias line illustrated in FIG. 10.

FIG. 12 is a cross-sectional view illustrating an imaging panel according to Application Example 1 of Embodiment 3.

FIG. 13 is a cross-sectional view illustrating an imaging panel according to Application Example 2 of Embodiment 3.

FIG. 14 is a cross-sectional view illustrating an imaging panel in Embodiment 4.

FIG. 15 is a cross-sectional view illustrating an imaging panel according to Application Example 1 of Embodiment 4.

FIG. 16 is a cross-sectional view illustrating an imaging panel according to Application Example 2 of Embodiment 4.

### MODE FOR CARRYING OUT THE INVENTION

An imaging panel according to an embodiment of the invention is an imaging panel that generates an image based on scintillation light that is obtained from X-rays transmitted through an object, and the imaging panel includes: a photoelectric conversion layer; a first electrode provided on a side irradiated with the X-rays, the first electrode and a second electrode forming a pair; and a first protection layer, wherein the first protection layer covers a side surface of the photoelectric conversion layer, and overlaps with the photoelectric conversion layer on the X-ray irradiated side so as to have an opening on an inner side with respect to an end of the photoelectric conversion layer, and the first electrode is arranged so as to be in contact with the photoelectric conversion layer in the opening, and to overlap with at least a part of the first protection layer (the first configuration).

According to the first configuration, the side surfaces of the photoelectric conversion layer is covered with the first protection layer, and in the photoelectric conversion layer, the portion thereof where the opening of the first protection layer is provided, which is on an inner side with respect to an end of the photoelectric conversion layer, is not covered with the first protection layer. The first electrode is arranged so as to be in contact with the photoelectric conversion layer in the opening of the first protection layer to overlap with at least apart of the first protection layer. In other words, the first electrode is formed after the first protection layer is formed. Therefore, when the photoelectric conversion layer is formed, the surfaces of the photoelectric conversion layer can be cleaned with use of hydrofluoric acid. This consequently makes it unlikely that off-leakage current would occur in the photoelectric conversion layer in the imaging panel of the present configuration.

The first configuration may be further characterized in that the photoelectric conversion layer includes a first amorphous semiconductor layer that has a first conductivity, an intrinsic amorphous semiconductor layer that is in contact with the first amorphous semiconductor layer, and a second amorphous semiconductor layer that is in contact with the intrinsic amorphous semiconductor layer, and has a second conductivity that is opposite to the first conductivity; the first protection layer has the opening on a top surface of the second amorphous semiconductor layer; the first electrode is in contact with of the second amorphous semiconductor layer in the opening; and a portion of the second amorphous semiconductor layer in an area where the opening is provided has a smaller thickness than that of a portion of the second amorphous semiconductor layer in an area that overlaps with the first protection layer (the second configuration). According to the second configuration, the portion of the second amorphous semiconductor layer in an area where the opening of the first protection layer is provided has a thickness smaller than that of the portion thereof in an area overlapping with the first protection layer. This improves the transmittance of the photoelectric conversion layer, thereby improving the quantum efficiency, as compared with a case where the second amorphous semiconductor layer has a uniform thickness.

The first or second configuration may be further characterized in that the first protection layer includes a first inorganic insulating film and a first organic insulating film, and the first organic insulating film is arranged so as to overlap on the first inorganic insulating film (the third configuration). According to the third configuration, a side surface of the photoelectric conversion layer is covered with the first inorganic insulating film and a first organic insulating film. This improves the coating of the side surface of the photoelectric conversion layer as compared with a case where the side surface of the photoelectric conversion layer is covered with a single insulating film, and consequently makes it unlikely that off-leakage current would occur in the photoelectric conversion layer.

The first or second configuration may be further characterized in that the first protection layer includes a first inorganic insulating film and a first organic insulating film; the first electrode is arranged so as to overlap on the first inorganic insulating film; and the first organic insulating film is provided in an upper layer with respect to the first electrode, and has an opening on an inner side with respect to the end of the photoelectric conversion layer and on an outer side with respect to the opening of the first inorganic insulating film (the fourth configuration).

The first or second configuration may be further characterized in that the first protection layer includes a first inorganic insulating film; and the first electrode is arranged so as to overlap on the first inorganic insulating film (the fifth configuration).

Any one of the first to fifth configurations may further include a second protection layer that is arranged so as to overlap with the first electrode and at least a part of the first protection layer (the sixth configuration). According to the sixth configuration, the upper part of the first electrode is covered with the second protection layer, whereby the first electrode can be protected.

The sixth configuration may be further characterized in that the second protection layer includes a second inorganic insulating film and a second organic insulating film; the second inorganic insulating film is in contact with the first electrode; and the second organic insulating film is provided on the second inorganic insulating film (the seventh configuration).

The sixth configuration may be further characterized in that the second protection layer includes a second inorganic insulating film and a second organic insulating film; and the second inorganic insulating film is in contact with the first electrode, and is arranged between the first inorganic insulating film and the second organic insulating film outside the opening (the eighth configuration).

Any one of the first to eighth configurations may further include a bias line that is in contact with the first electrode, and to which a predetermined bias voltage is applied (the ninth configuration). With the ninth configuration, a bias voltage can be applied to the first electrode.

The ninth configuration may be further characterized in that the bias line is in contact with the first electrode outside the opening (the tenth configuration). With the tenth configuration, the transmittance of the photoelectric conversion layer can be improved, as compared with a case where the bias line is provided inside the opening.

The ninth or tenth configuration may be further characterized in that the bias line is provided in an upper layer with respect to the first protection layer (the eleventh configuration).

Any one of the ninth to eleventh configurations may be further characterized by further including a conductive film that covers the bias line (the twelfth configuration). With the twelfth configuration, the corrosion of the bias line can be prevented.

Any one of the first to twelfth configurations may be further characterized in that the opening has an area at a ratio of 70.56% or more with respect to an area on the X-ray irradiated side of the photoelectric conversion layer (the thirteenth configuration). With the thirteenth configuration, the quantum efficiency of the photoelectric conversion layer can be improved.

A method for producing an imaging panel according to an embodiment of the present invention is a method for producing an imaging panel that generates an image based on scintillation light that is obtained from X-rays transmitted through an object, and the imaging panel producing method includes the steps of: sequentially forming a first amorphous semiconductor layer having a first conductivity, an intrinsic amorphous semiconductor layer, and a second amorphous semiconductor layer having a second conductivity that is opposite to the first conductivity, on a substrate; forming a photoelectric conversion layer by etching the first amorphous semiconductor layer, the intrinsic amorphous semiconductor layer, and the second amorphous semiconductor layer; carrying out a removal treatment for removing matters that adhere to a surface of the photoelectric conversion layer; forming a first protection layer after the removal treatment, the first protection layer covering a side surface of the photoelectric conversion layer, and overlapping with a part of the photoelectric conversion layer on the X-ray irradiated side so as to have an opening on an inner side with respect to an end of the photoelectric conversion layer; and forming a first electrode arranged so as to be in contact with the photoelectric conversion layer in the opening and to overlap with at least apart of the first protection layer. The first electrode forms a pair with a second electrode (the first producing method).

According to the first producing method, a treatment for removing matters that adhere to the surface of the photoelectric conversion layer is carried out before the first protection layer is formed, which makes it possible to suppress the occurrence of off-leakage current caused by matters adhering to the photoelectric conversion layer.

The first producing method may be further characterized in that the removal treatment includes a cleaning treatment with use of hydrofluoric acid (the second producing method). With the second producing method, organic matters and the like adhering to the surface of the photoelectric conversion layer can be removed.

The first or second producing method may be further characterized in that the opening in the first protection layer is formed by performing wet etching with use of hydrofluoric acid to the first protection layer (the third producing method). With the third producing method, matters adhering to the surface of the photoelectric conversion layer can be removed.

Any one of the first to third producing method may be further characterized in that the opening has an area at a ratio of 70.56% or more with respect to an area on the X-ray irradiated side of the photoelectric conversion layer (the fourth producing method). With the fourth producing method, the quantum efficiency of the photoelectric conversion layer can be improved.

The following description describes embodiments of the present invention in detail, while referring to the drawings. Identical or equivalent parts in the drawings are denoted by the same reference numerals, and the descriptions of the same are not repeated.

### Embodiment 1

### (Configuration)

FIG. 1 schematically illustrates an X-ray imaging device in the present embodiment. The X-ray imaging device 100 includes an imaging panel 1 and a control unit 2. The control unit 2 includes a gate control unit 2A and a signal reading unit 2B. X-rays are projected from the X-ray source 3 to an object S, and X-rays transmitted through the object S are converted into fluorescence (hereinafter referred to as scintillation light) in a scintillator 1A arranged above the imaging panel 1. The X-ray imaging device 100 acquires an X-ray image by picking up the scintillation light with the imaging panel 1 and the control unit 2.

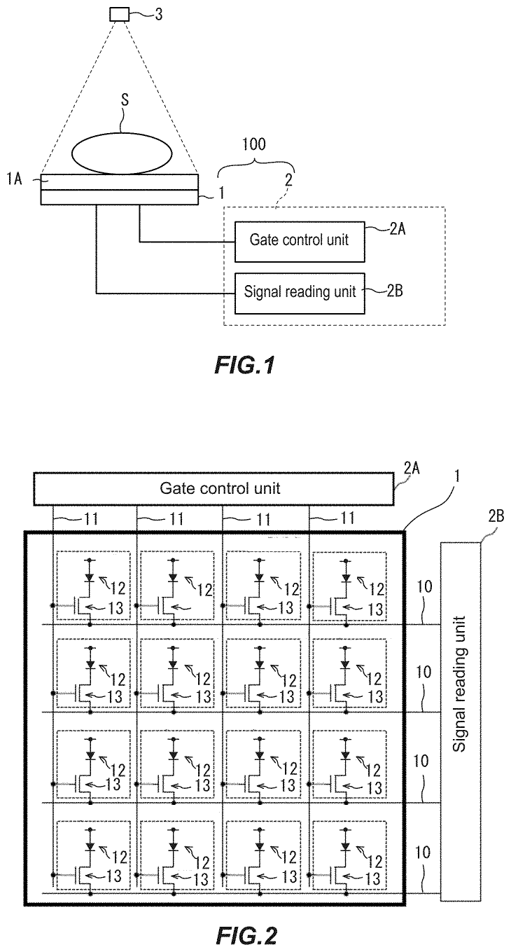

FIG. 2 schematically illustrates a schematic configuration of the imaging panel 1. As illustrated in FIG. 2, a plurality of source lines 10, and a plurality of gate lines 11 intersecting with the source lines 10 are formed in the imaging panel 1. The gate lines 11 are connected with the gate control unit 2A, and the source lines 10 are connected with the signal reading unit 2B.

The imaging panel 1 includes TFTs 13 connected to the source lines 10 and the gate lines 11, at positions at which the source lines 10 and the gate lines 11 intersect. Further, photodiodes 12 are provided in areas surrounded by the source lines 10 and the gate lines 11 (hereinafter referred to as pixels). In each pixel, scintillation light obtained by converting X-rays transmitted through the object S is converted by the photodiode 12 into charges according to the amount of the light.

The gate lines 11 in the imaging panel 1 are sequentially switched by the gate control unit 2A into a selected state, and the TFT 13 connected to the gate line 11 in the selected state is turned ON. When the TFT 13 is turned ON, a signal according to the charges obtained by the conversion by the photodiode 12 is output through the source line 10 to the signal reading unit 2B.

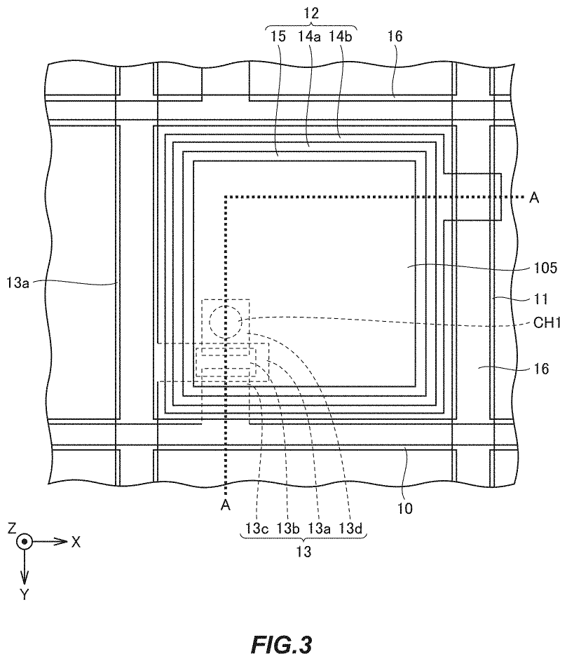

FIG. 3 is an enlarged plan view of one pixel portion of the imaging panel 1 illustrated in FIG. 2. As illustrated in FIG. 3, the photodiode 12 and the TFT 13 are provided in the pixel surrounded by the gate lines 11 and the source lines 10. The photodiode 12 includes a lower electrode 14a and an upper electrode 14b as a pair of electrodes, and a photoelectric conversion layer 15. The upper electrode 14b is provided above the photoelectric conversion layer 15, i.e., on the side to which the X rays are projected from the X-ray source 3 (see FIG. 1). The TFT 13 includes a gate electrode 13a integrated with the gate line 11, a semiconductor active layer 13b, a source electrode 13c integrated with the source line 10, and a drain electrode 13d. Further, a bias line 16 is arranged so as to overlap with the gate line 11 and the source line 10 when viewed in a plan view. The bias line 16 supplies a bias voltage to the photodiode 12. In the pixel, a contact hole CH1 for connecting the drain electrode 13d and the lower electrode 14a with each other is provided.

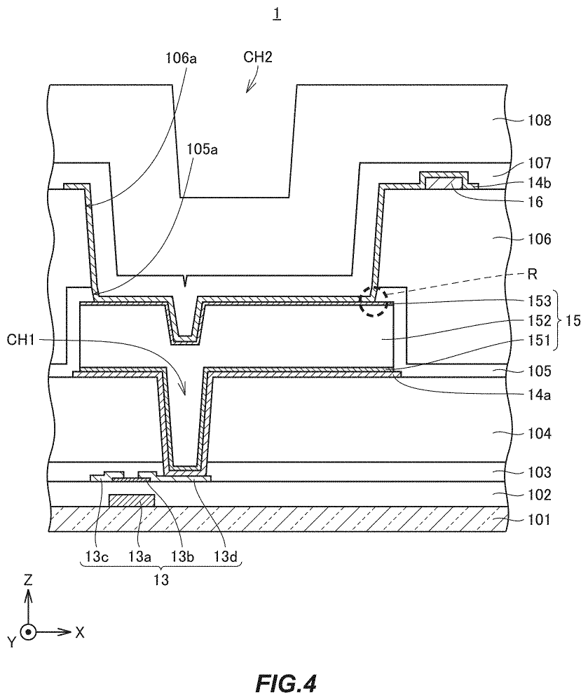

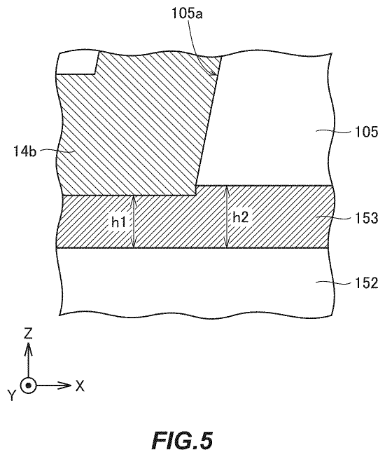

Here a cross-sectional view of the pixel illustrated in FIG. 3 taken along line A-A is illustrated in FIG. 4. As illustrated in FIG. 4, the elements in the pixel are arranged on the substrate 101. The substrate 101 is a substrate having an insulating property, which is formed with, for example, a glass substrate.

On the substrate 101, the gate electrode 13a integrated with the gate line 11 (see FIG. 3), and a gate insulating film 102 are formed.

The gate electrode 13a and the gate line 11 are made of, for example, a metal such as aluminum (Al), tungsten (W), molybdenum (Mo), molybdenum nitride (MoN), tantalum (Ta), chromium (Cr), titanium (Ti), or copper (Cu), an alloy of any of these metals, or a metal nitride of these metals. In the present embodiment, the gate electrode 13a and the gate line 11 have a laminate structure in which a metal film made of molybdenum nitride and a metal film made of aluminum are laminated in this order. Regarding thicknesses of these metal films, for example, the metal film made of molybdenum nitride has a thickness of 100 nm, and the metal film made of aluminum has a thickness of 300 nm.

The gate insulating film 102 covers the gate electrode 13a. The gate insulating film 102 may be formed with, for example, silicon oxide (SiOₓ), silicon nitride (SiNₓ), silicon oxide nitride (SiOₓN_{y})(x>y), or silicon nitride oxide (SiNₓO_{y})(x>y). In the present embodiment, the gate insulating film 102 is formed with a laminate film obtained by laminating silicon oxide (SiOₓ) and silicon nitride (SiNₓ) in the order, and regarding the thicknesses of these films, the film of silicon oxide (SiOₓ) has a thickness of 50 nm, and the film of silicon nitride (SiNₓ) has a thickness of 400 nm.

The semiconductor active layer 13b, as well as the source electrode 13c and the drain electrode 13d connected with the semiconductor active layer 13b are formed on the gate electrode 13a with the gate insulating film 102 being interposed therebetween.

The semiconductor active layer 13b is formed in contact with the gate insulating film 102. The semiconductor active layer 13b is made of an oxide semiconductor. For forming the oxide semiconductor, for example, the following material may be used: InGaO₃(ZnO)₅; magnesium zinc oxide (MgₓZn₁₋ₓO); cadmium zinc oxide (CdₓZn₁₋ₓO); cadmium oxide (CdO); or an amorphous oxide semiconductor containing indium (In), gallium (Ga), and zinc (Zn) at a predetermined ratio. In the present embodiment, the semiconductor active layer 13b is made of an amorphous oxide semiconductor containing indium (In), gallium (Ga), and zinc (Zn) at a predetermined ratio, and has a thickness of, for example, 70 nm.

The source electrode 13c and the drain electrode 13d are arranged so as to be in contact with a part of the semiconductor active layer 13b on the gate insulating film 102. The source electrode 13c is integrated with the source line 10 (see FIG. 3). The drain electrode 13d is connected with the lower electrode 14a through the contact hole CH1.

The source electrode 13c and the drain electrode 13d are formed in the same layer, and are made of, for example, a metal such as aluminum (Al), tungsten (W), molybdenum (Mo), tantalum (Ta), chromium (Cr), titanium (T), or copper (Cu), or alternatively, an alloy of any of these, of a metal nitride of any of these. Further, as the material for the source electrode 13c and the drain electrode 13d, the following material may be used: a material having translucency such as indium tin oxide (ITO), indium zinc oxide (IZO), indium tin oxide (ITSO) containing silicon oxide, indium oxide (In₂O₃), tin oxide (SnO₂), zinc oxide (ZnO), or titanium nitride; or a material obtained by appropriately combining any of these.

The source electrode 13c and the drain electrode 13d may be, for example, a laminate of a plurality of metal films. More specifically, the source electrode 13c and the drain electrode 13d have a laminate structure in which a metal film made of molybdenum nitride (MoN), a metal film made of aluminum (Al), and a metal film made of molybdenum nitride (MoN) are laminated in this order. Regarding the thicknesses of the films, the metal film in the lower layer, which is made of molybdenum nitride (MoN), has a thickness of 100 nm, the metal film made of aluminum (Al) has a thickness of 500 nm, and the metal film in the upper layer, which is made of molybdenum nitride (MoN), has a thickness of 50 nm.

A first insulating film 103 is provided so as to cover the source electrode 13c and the drain electrode 13d. The first insulating film 103 may have a single layer structure made of silicon oxide (SiO₂) or silicon nitride (SiN), or a laminate structure obtained by laminating silicon nitride (SiN) and silicon oxide (SiO₂) in this order.

On the first insulating film 103, a second insulating film 104 is formed. Above the drain electrode 13d, a contact hole CH1 is formed. The contact hole CH1 passes through the second insulating film 104 and the first insulating film 103. The second insulating film 104 is made of an organic transparent resin, for example, acrylic resin or siloxane-based resin, and has a thickness of, for example, 2.5 μm.

On the second insulating film 104, a lower electrode 14a is formed. The lower electrode 14a is connected with the drain electrode 13d through the contact hole CH1. The lower electrode 14a is formed with, for example, a metal film containing molybdenum nitride (MoN), and has a thickness of, for example, 200 nm.

On the lower electrode 14a, the photoelectric conversion layer 15 is formed. The photoelectric conversion layer 15 is composed of the n-type amorphous semiconductor layer 151, the intrinsic amorphous semiconductor layer 152, and the p-type amorphous semiconductor layer 153, which are laminated in the order. In this example, the length in the X-axis direction of the photoelectric conversion layer 15 is shorter than the length in the X-axis direction of the lower electrode 14a.

The n-type amorphous semiconductor layer 151 is made of amorphous silicon doped with an n-type impurity (for example, phosphorus). The n-type amorphous semiconductor layer 151 has a thickness of, for example, 30 nm.

The intrinsic amorphous semiconductor layer 152 is made of intrinsic amorphous silicon. The intrinsic amorphous semiconductor layer 152 is formed in contact with the n-type amorphous semiconductor layer 151. The intrinsic amorphous semiconductor layer has a thickness of, for example, 1000 nm.

The p-type amorphous semiconductor layer 153 is made of amorphous silicon doped with a p-type impurity (for example, boron). The p-type amorphous semiconductor layer 153 is formed in contact with the intrinsic amorphous semiconductor layer 152. The p-type amorphous semiconductor layer 153 has a thickness of, for example, 5 nm.

On the second insulating film 102, a third insulating film 105 as a first protection layer is formed. The third insulating film 105 covers side surfaces of the lower electrode 14a and the photoelectric conversion layer 15, and has an opening 105a above the photoelectric conversion layer 15. The third insulating film 105 is, for example, an inorganic insulating film made of silicon nitride (SiN), and has a thickness of, for example, 300 nm.

Here, FIG. 5 illustrates an enlarged view of a line frame R illustrated in FIG. 4. As illustrated in FIG. 5, a portion of the p-type amorphous semiconductor layer 153 in the present embodiment, overlapping with the upper electrode 14b, has a thickness h1 smaller than a thickness h2 of a portion thereof that overlaps with the third insulating film 105. The reason why the p-type amorphous semiconductor layer 153 has a non-uniform thickness is described below in the description about the process for producing the imaging panel.

With reference to FIG. 4 again, on the third insulating film 105, the fourth insulating film 106 as the first protection layer is provided. The fourth insulating film 106 has an opening 106a at a position that overlaps with the opening 105a of the third insulating film 105. The contact hole CH2 is formed with the openings 105a and 106a. The fourth insulating film 106 is made of an organic transparent resin, for example, acrylic resin or siloxane-based resin, and has a thickness of, for example, 2.5 μm.

Incidentally, it is desirable that the openings 105a and 106a of the third and fourth insulating films 105 and 106 as the first protection layers are positioned on an inner side with respect to the ends of the photoelectric conversion layer 15, and has an area at a ratio of about 70.56% or more with respect to an area on the X-ray irradiated side of the photoelectric conversion layer 15, i.e., on the p-type amorphous semiconductor layer 153 side thereof. With such a configuration, the quantum efficiency of the photoelectric conversion layer 15 is improved.

On the fourth insulating film 106, the bias line 16 is formed. The bias line 16 has a laminate structure that is obtained by laminating, for example, a metal film made of molybdenum nitride (MoN), a metal film made of aluminum (Al), and a metal film made of titanium (Ti) in this order. The films of molybdenum nitride (MoN), aluminum (Al), and titanium (Ti) have thicknesses of, for example, 100 nm, 300 nm, and 50 nm, respectively.

On the fourth insulating film 106 and the photoelectric conversion layer 15, the upper electrode 14b is provided. The upper electrode 14b covers the bias line 16 and the p-type amorphous semiconductor layer 153 in the contact hole CH2. The upper electrode 14b is made of, for example, indium tin oxide (ITO), and has a thickness of, for example, 70 nm.

The bias line 16 is connected to the control unit 2 (see FIG. 1). The bias line 16 applies a bias voltage through the contact hole CH2 to the upper electrode 14b, the bias voltage being input from the control unit 2.

On the fourth insulating film 106 and the transparent conductive film 17, a fifth insulating film 107 as the second protection film is provided. The fifth insulating film 107 is an inorganic insulating film made of, for example, silicon nitride (SiN), and has a thickness of, for example, 200 nm.

On the fifth insulating film 107, a sixth insulating film 108 as the second protection film is provided. The sixth insulating film 108 is made of an organic transparent resin, for example, acrylic resin or siloxane-based resin, and has a thickness of, for example, 2.0 μm.

### (Method for Producing Imaging Panel 1)

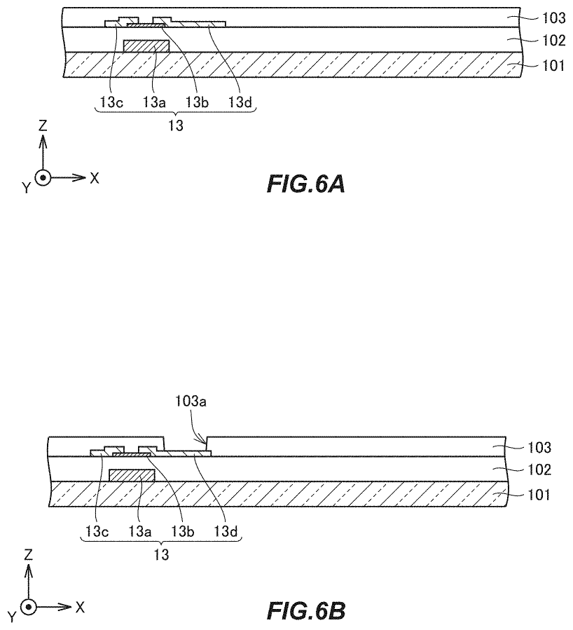

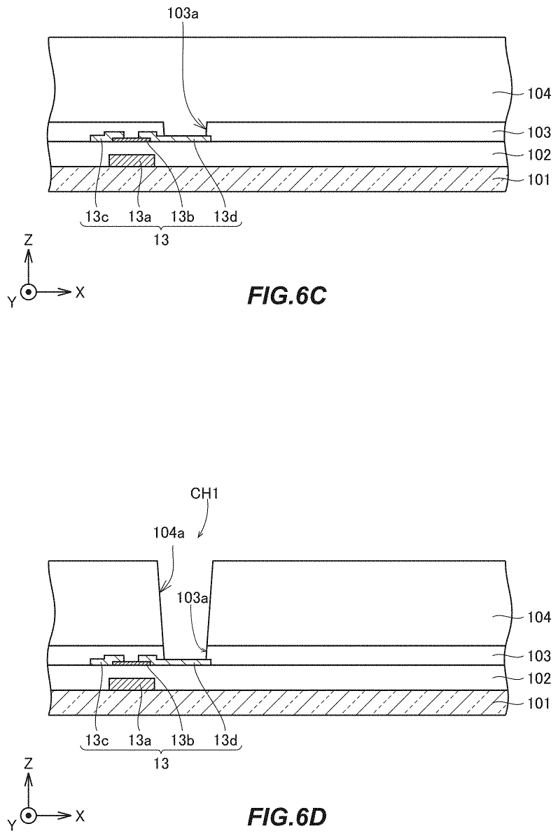

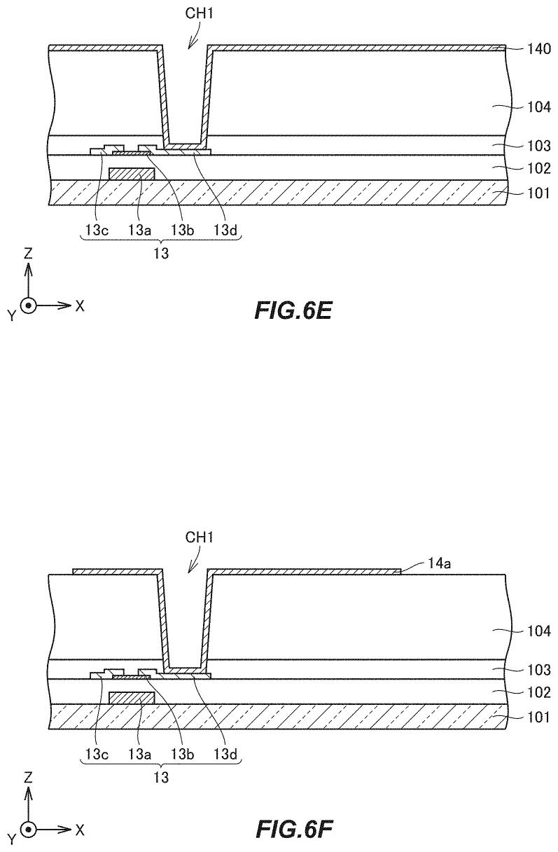

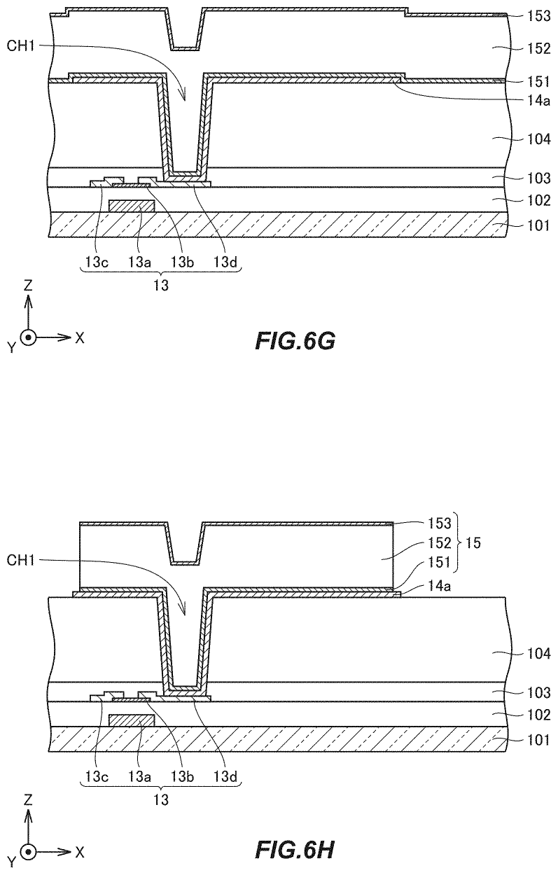

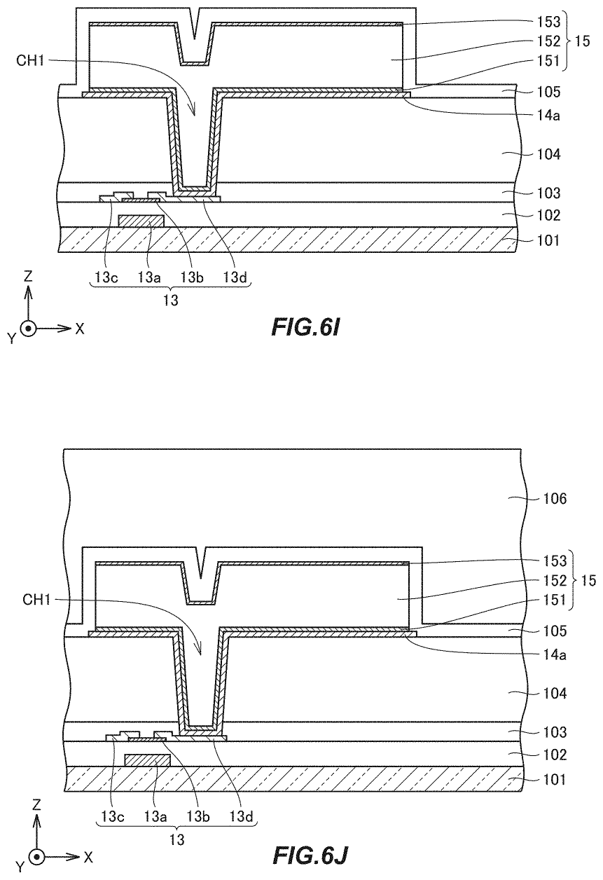

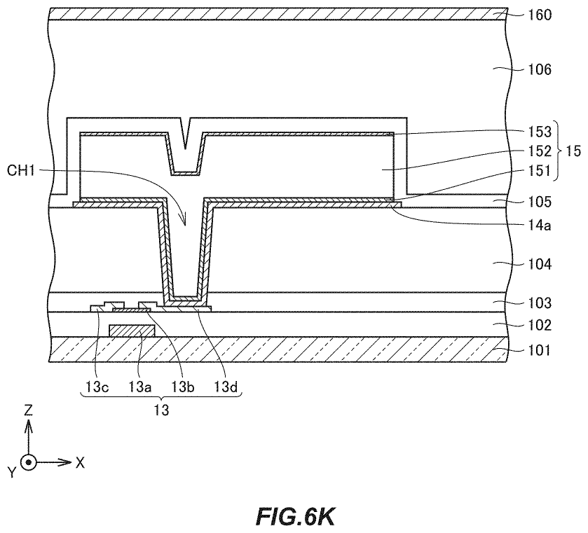

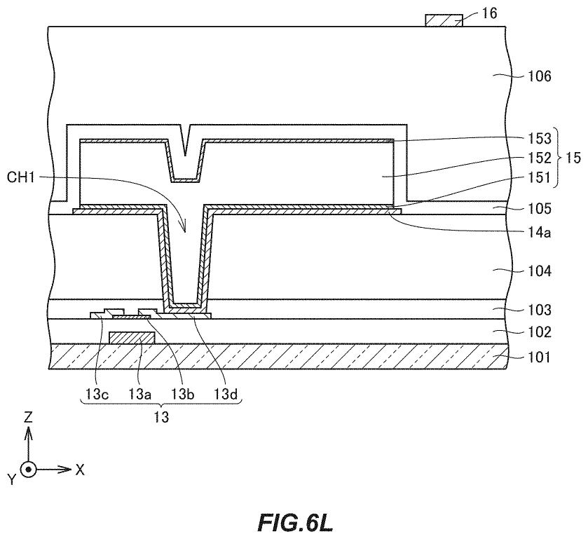

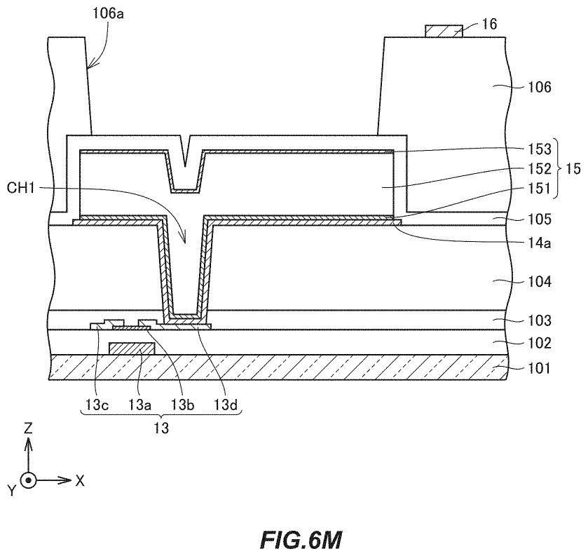

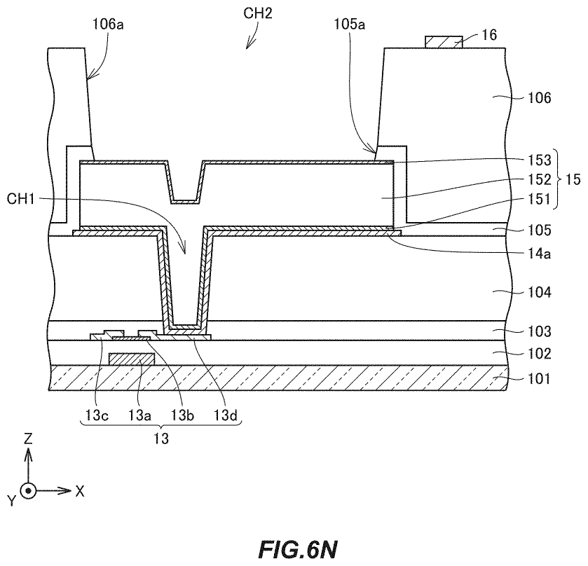

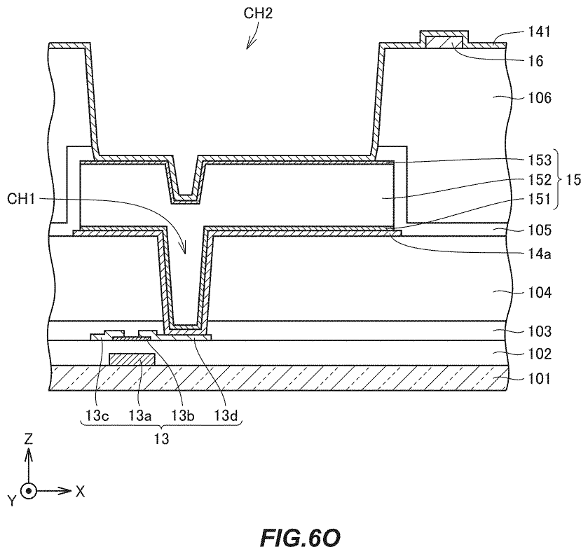

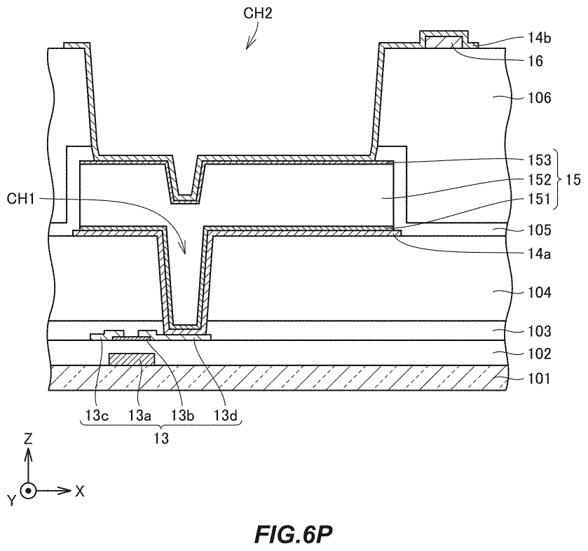

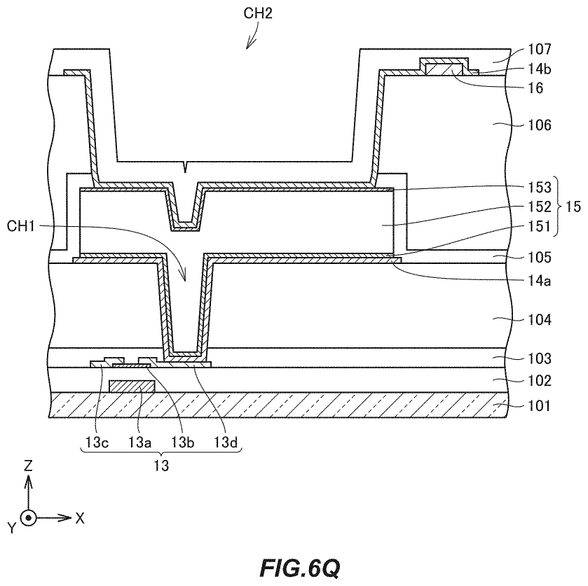

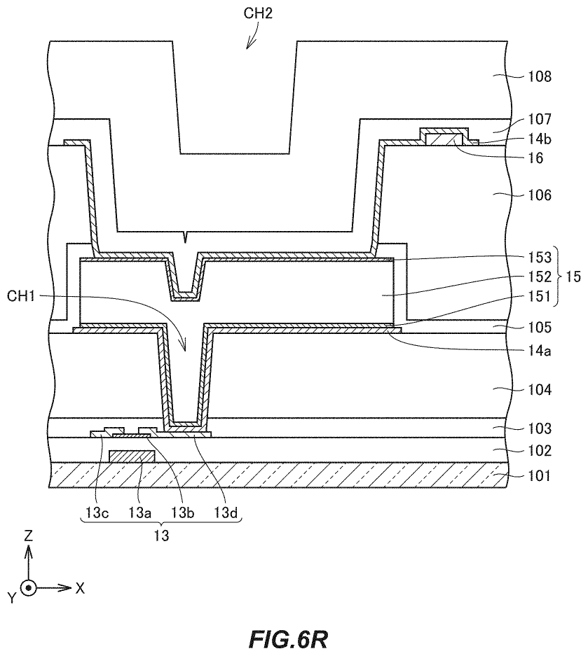

Next, the following description describes a method for producing the imaging panel 1. FIGS. 6A to 6R are cross-sectional views (taken along line A-A in FIG. 3) in respective steps in the method for producing of the imaging panel 1.

As illustrated in FIG. 6A, the gate insulating film 102 and the TFT 13 are formed on the substrate 101 by a known method, and the first insulating film 103 made of silicon nitride (SiN) is formed by, for example, plasma CVD, so as to cover the TFT 13.

Subsequently, a heat treatment at about 350° C. is applied to an entire surface of the substrate 101, and photolithography and wet etching are carried out so that the first insulating film 103 is patterned, whereby an opening 103a is formed on the drain electrode 13d (see FIG. 6B).

Next, the second insulating film 104 made of acrylic resin or siloxane-based resin is formed on the first insulating film 103 by, for example, slit coating (see FIG. 6C).

Then, an opening 104a of the second insulating film 104 is formed on the opening 103a by photolithography. Through these steps, the contact hole CH2 composed of the openings 103a and 104a is formed (see FIG. 6D).

Subsequently, a metal film 140 made of molybdenum nitride (MoN) is formed on the second insulating film 104 by, for example, sputtering (see FIG. 6E).

Then, photolithography and wet etching are carried out so that the metal film 140 is patterned. As a result, the lower electrode 14a, which is connected with the drain electrode 13d through the contact hole CH1, is formed on the second insulating film 104 (see FIG. 6F).

Next, the n-type amorphous semiconductor layer 151, the intrinsic amorphous semiconductor layer 152, and the p-type amorphous semiconductor layer 153 are formed in the stated order so as to cover the second insulating film 104 and the lower electrode 14a, for example, by plasma CVD (see FIG. 6G).

Then, photolithography and dry etching are carried out so that the n-type amorphous semiconductor layer 151, the intrinsic amorphous semiconductor layer 152, and the p-type amorphous semiconductor layer 153 are patterned. As a result, the photoelectric conversion layer 15 is formed (see FIG. 6H).

In the step illustrated in FIG. 6H, organic matters, naturally formed oxide films, and the like adhere to the surfaces of the photoelectric conversion layer 15 when patterning is performed. In the present embodiment, therefore, after the photoelectric conversion layer 15 is formed, the surface of the photoelectric conversion layer 15 is subjected to a cleaning treatment with use of hydrofluoric acid, and a reduction treatment with use of hydrogen plasma.

Next, the third insulating film 105 made of silicon nitride (SiN) is formed by, for example, plasma CVD so as to cover the surface of the photoelectric conversion layer 15 (see FIG. 6I).

Subsequently, the fourth insulating film 106 made of acrylic resin or siloxane-based resin is formed on the third insulating film 105 by, for example, slit coating (see FIG. 6J).

Further, a metal film 160 is formed by laminating molybdenum nitride (MoN), aluminum (Al), and titanium (Ti) in this order on the fourth insulating film 106 by, for example, sputtering (see FIG. 6K).

Then, photolithography and wet etching are carried out so that the metal film 160 is patterned and the bias line 16 is formed (see FIG. 6L).

Next, an opening 106a of the fourth insulating film 106 is formed above the photoelectric conversion layer 15 by photolithography (see FIG. 6M).

Subsequently, photolithography and wet etching are carried out so that an opening 105a of the third insulating film 105 is formed below the opening 106a. As a result, the contact hole CH2 composed of the openings 105a and 106a is formed (see FIG. 6N).

The contact hole CH2 is positioned on an inner side with respect to the ends of the photoelectric conversion layer 15, and has an area at a ratio of about 70.56% or more with respect to an area on the X-ray irradiated side of the photoelectric conversion layer 15, i.e., on the p-type amorphous semiconductor layer 153 side thereof. In order that such an opening is formed, every end of the mask pattern may be arranged at a distance in a range of 1 μm to 8 μm, both inclusive, from the ends of the photoelectric conversion layer 15, when the openings in the third insulating film 105 and the fourth insulating film 106 are formed. In other words, in a case where the area of the contact hole CH2 is less than 70.56% of the area on the X-ray irradiated side of the photoelectric conversion layer 15, any displacement of the mask patterns causes the opening to be formed outside the photoelectric conversion layer 15, thereby deteriorating the properties of the photoelectric conversion layer 15.

Wet etching with respect to the third insulating film 105 is carried out with use of hydrofluoric acid. Organic matters, naturally formed oxide films, and the like adhering to the surface of the p-type amorphous semiconductor layer 153 of the photoelectric conversion layer 15 are removed when being exposed to hydrofluoric acid. Further, in this step, the portion of the third insulating film 105 where the opening 105a is to be formed is also etched by the wet etching in the p-type amorphous semiconductor layer 153.

Further, in the step illustrated in FIG. 6N, after the wet etching with respect to the third insulating film 105, the surface of the p-type amorphous semiconductor layer 153 where the opening 105a is provided is cleaned with use of hydrofluoric acid. As a result, naturally formed oxide films adhering to the surface of the photoelectric conversion layer 15 are removed. Besides, in the cleaning treatment, the portion of the p-type amorphous semiconductor layer 153 on which the opening 105a of the third insulating film 105 is provided is etched, whereby the thickness of the portion of the p-type amorphous semiconductor layer 153 on which the opening 105a is provided becomes further smaller than the thickness of the portion of the p-type amorphous semiconductor layer 153 covered with the third insulating film 105. As a result, as illustrated in FIG. 5, the thickness h1 of the opening 105a portion of the p-type amorphous semiconductor layer 153 on which the third insulating film 105 is not provided is smaller than the thickness h2 of the portion of the p-type amorphous semiconductor layer 153 on which the third insulating film 105 is provided.

Next, a transparent conductive film 141 made of ITO is formed by, for example, sputtering, so as to cover the p-type amorphous semiconductor layer 153, the bias line 16, and the fourth insulating film 106 (see FIG. 6O).

Then, photolithography and dry etching are carried out so that the transparent conductive film 141 is patterned. As a result, the upper electrode 14b that is connected with the bias line 16, and is connected with the photoelectric conversion layer 15 through the contact hole CH2 is formed (see FIG. 6P)

Subsequently, for example, the fifth insulating film 107 made of silicon nitride (SiN) is formed by, for example, plasma CVD so as to cover the upper electrode 14b (see FIG. 6O).

Next, the sixth insulating film 108 made of acrylic resin or siloxane-based resin is formed on the fifth insulating film 107 by, for example, slit coating (see FIG. 6R).

The method described above is the method for producing the imaging panel 1 in the present embodiment. As described above, in the present embodiment, after the photoelectric conversion layer 15 is formed, the surface of the photoelectric conversion layer 15 is subjected to cleaning with use of hydrofluoric acid, and a reduction treatment with use of hydrogen plasma. This allows matters adhering to the surface of the photoelectric conversion layer 15, such as organic matters and naturally formed oxide films, to be removed. Besides, in the present embodiment, side walls of the photoelectric conversion layer 15 are covered with the third insulating film 105 and the fourth insulating film 105 as the first protection films, and the fifth insulating film 107 and the sixth insulating film 108 as the second protection films, while the upper electrode 14b is covered with the fifth insulating film 107 and the sixth insulating film 108 as the second protection films. This consequently makes it unlikely that off-leakage current caused by contaminants or the like would occur in the photoelectric conversion layer 15.

Further, the surface of the p-type amorphous semiconductor layer 153 is exposed to hydrofluoric acid when the opening 105a of the third insulating film 105 is formed and after the same. Consequently, matters adhering to the surface of the p-type amorphous semiconductor layer 153 are removed, whereby excellent contact can be obtained between the upper electrode 14b and the p-type amorphous semiconductor layer 153.

Besides, the surface of the p-type amorphous semiconductor layer 153 is etched when being exposed to hydrofluoric acid, whereby the thickness of the portion of the p-type amorphous semiconductor layer 153 on which the opening 105a is provided, i.e., the third insulating film 105 is not provided, becomes smaller than the thickness of the portion of the same on which the third insulating film 105 overlaps (see FIG. 5). This improves the transmittance of the photoelectric conversion layer 15, thereby improving the quantum efficiency in the photoelectric conversion layer 15.

### (Operation of X-Ray Imaging Device 100)

Here, operations of the X-ray imaging device 100 illustrated in FIG. 1 are described. First, X-rays are emitted from the X-ray source 3. Here, the control unit 2 applies a predetermined voltage (bias voltage) to the bias line 16 (see FIG. 3 and the like). X-rays emitted from the X-ray source 3 transmit an object S, and are incident on the scintillator 1A. The X-rays incident on the scintillator 1A are converted into fluorescence (scintillation light), and the scintillation light is incident on the imaging panel 1. When the scintillation light is incident on the photodiode 12 provided in each pixel in the imaging panel 1, the scintillation light is changed to charges by the photodiode 12 in accordance with the amount of the scintillation light. A signal according to the charges obtained by conversion by the photodiode 12 is read out through the source line 10 to the signal reading unit 2B (see FIG. 2 and the like) when the TFT 13 (see FIG. 3 and the like) is in the ON state according to a gate voltage (positive voltage) that is output from the gate control unit 2A through the gate line 11. Then, an X-ray image in accordance with the signal thus read out is generated in the control unit 2.

### Embodiment 21

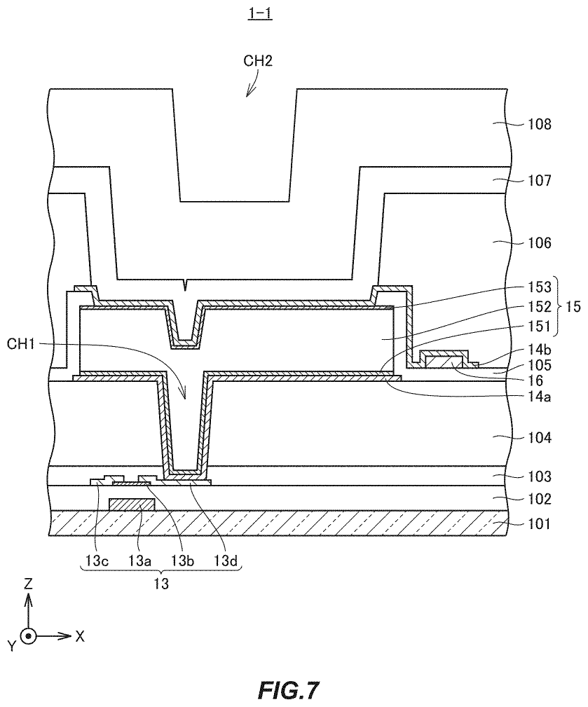

FIG. 7 schematically illustrates a cross section of an imaging panel in Embodiment 2. In FIG. 7, the same configurations as those in Embodiment 1 are denoted by the same reference symbols as those in Embodiment 1. The following description principally describes configurations different from those in Embodiment 1.

As illustrated in FIG. 7, in the present embodiment, the bias line 16 is provided on the third insulating film 105, outside the photoelectric conversion layer 15.

The upper electrode 14b is provided on the third insulating film 105, so as to cover the p-type amorphous semiconductor layer 153 and the bias line 16.

The fourth insulating film 106 is provided outside the contact hole CH2 so as to overlap with the upper electrode 14b and the third insulating film 105. In other words, the fourth insulating film 106 is provided in an upper layer with respect to the upper electrode 14b, and has an opening on an inner side with respect to ends of the photoelectric conversion layer 15, and on an outer side with respect to the opening of the third insulating film 105.

In the present embodiment, side surfaces of the photoelectric conversion layer 15 are covered with the third insulating film 105 as the first protection film. The bias line 16 is covered with the upper electrode 14b on the third insulating film 105.

The method for producing the imaging panel 1_1 in the present embodiment is performed as follows. First, the above-described steps illustrated in FIGS. 6A to 6I are carried out.

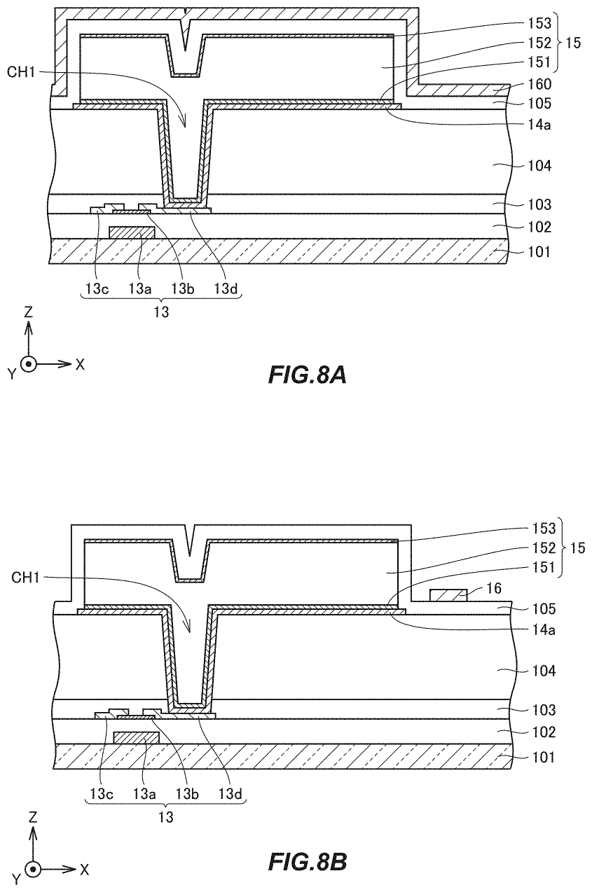

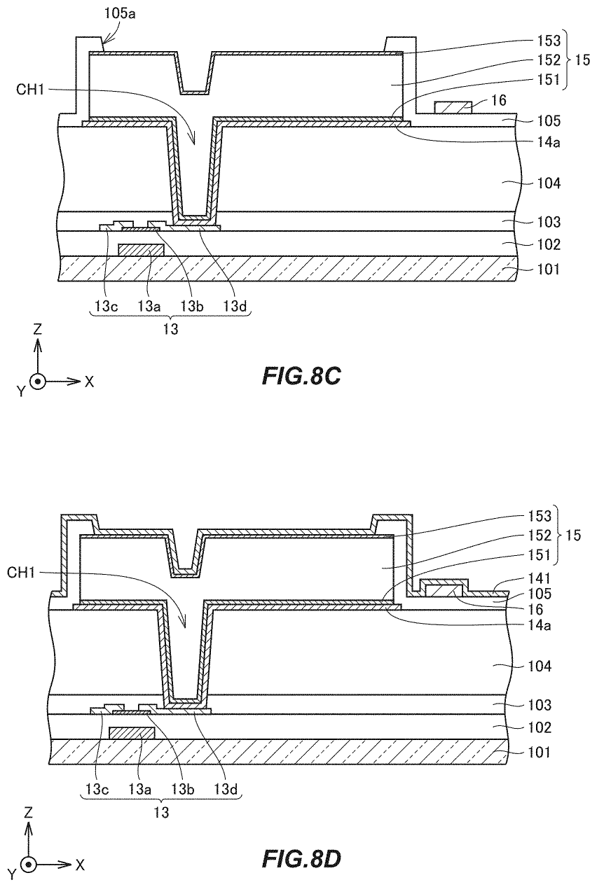

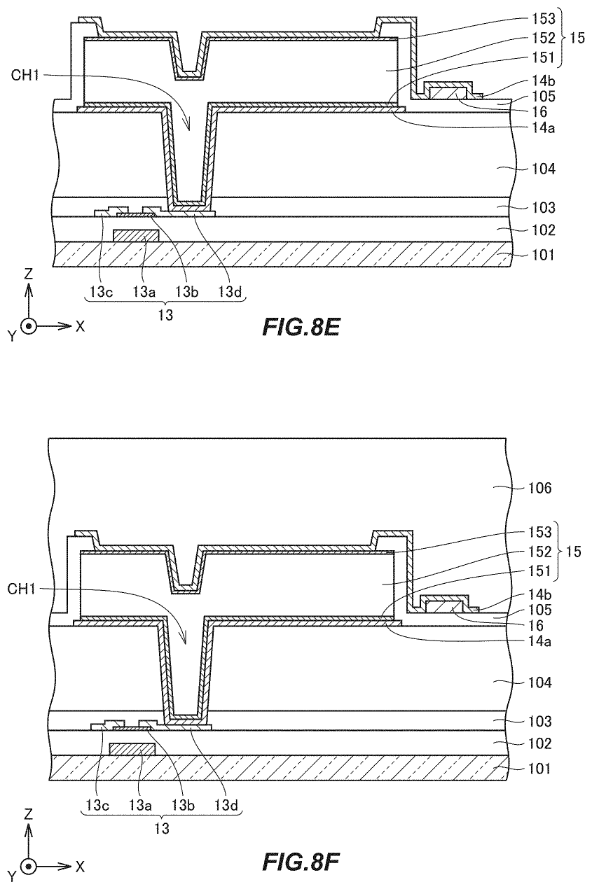

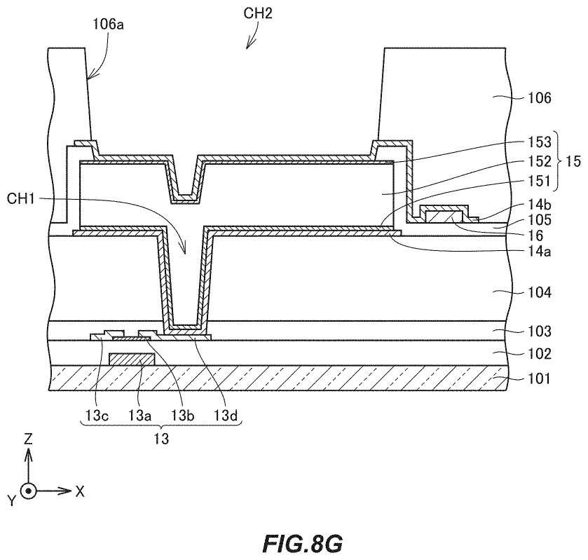

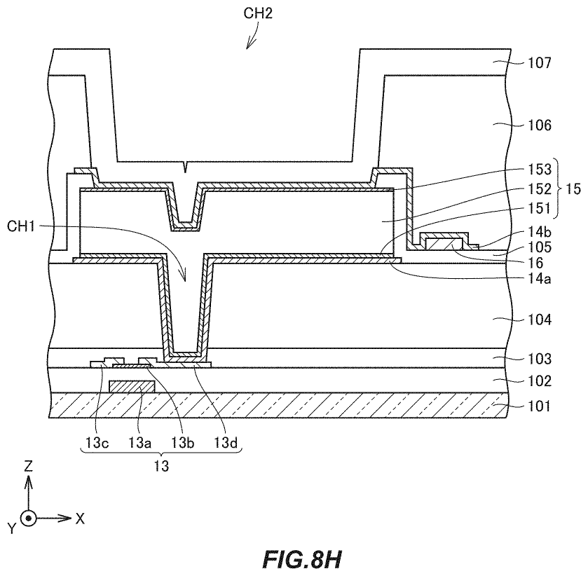

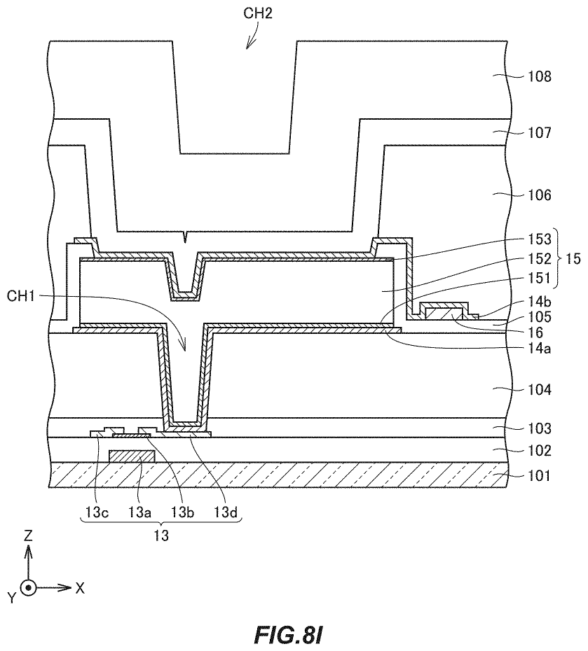

After the step illustrated in FIG. 6I, a metal film 160 is formed on the third insulating film 105 in the same manner as that in the step illustrated in FIG. 6K (see FIG. 8A), and subsequently, the metal film 160 is patterned so that the bias line 16 is formed in the same manner as that in the step illustrated in FIG. 6L (see FIG. 8B).

Next, the opening 105a of the third insulating film 105 is formed above the photoelectric conversion layer 15 in the same manner as that in the step illustrated in FIG. 6N (see FIG. 8C).

Subsequently, a transparent conductive film 141 is formed so as to cover the opening 105a and the bias line 16 in the same manner as that in the step illustrated in FIG. 6O (see FIG. 8D), and the transparent conductive film 141 is patterned so that the upper electrode 14b is formed in the same manner as that in the step illustrated in FIG. 6P (see FIG. 8E). The upper electrode 14b is connected with the bias line 16, and is connected with the photoelectric conversion layer 15 through the contact hole CH2.

Next, the fourth insulating film 106 is formed so as to cover the upper electrode 14b in the same manner as that in the step illustrated in FIG. 6J (see FIG. 8F). Then, the opening 106a of the fourth insulating film 106 is formed at a position that overlaps with the opening 105a of the third insulating film 105, in the same manner as that in the step illustrated in FIG. 6M (see FIG. 8G).

Then, in the same manner as that in the step illustrated in FIG. 6R, the fifth insulating film 107 covering the fourth insulating film 106 is formed (see FIG. 8H), and the sixth insulating film 108 covering the fifth insulating film 107 is formed (see FIG. 8I)

In the present embodiment as well, the step illustrated in FIG. 6H is carried out in the same manner as that in Embodiment 1. In other words, when the photoelectric conversion layer 15 is formed, the surface of the photoelectric conversion layer 15 is subjected to a cleaning treatment with use of hydrofluoric acid, and a reduction treatment with use of hydrogen plasma. Besides, side walls of the photoelectric conversion layer 15 are covered with the third insulating film 105 and the fourth insulating film 105 as the first protection films, and the fifth insulating film 107 and the sixth insulating film 108 as the second protection films, while the upper electrode 14b is covered with the fifth insulating film 107 and the sixth insulating film 108 as the second protection films. This suppresses the occurrence of off-leakage current caused by matters adhering to the surface of the photoelectric conversion layer 15, such as organic matters and naturally formed oxide films.

Further, in the step for forming the opening 105a of the third insulating film 105 (FIG. 8C), wet etching with use of hydrofluoric acid is carried out as is the case with the step illustrated in FIG. 6N in Embodiment 1, and the cleaning is carried out by using hydrofluoric acid with respect to the p-type amorphous semiconductor layer 153 in the opening 105a. This makes it possible to obtain excellent contact between the upper electrode 14b and the p-type amorphous semiconductor layer 153. Besides, in the present embodiment as well, the portion of the p-type amorphous semiconductor layer 153 on which the opening 105a is provided, that is, the third insulating film 105 is not provided, has a thickness smaller than the thickness of the portion of the p-type amorphous semiconductor layer 153 on which the third insulating film 105 is provided. This improves the transmittance of the photoelectric conversion layer 15, thereby improving the quantum efficiency in the photoelectric conversion layer 15.

### Application Example 1

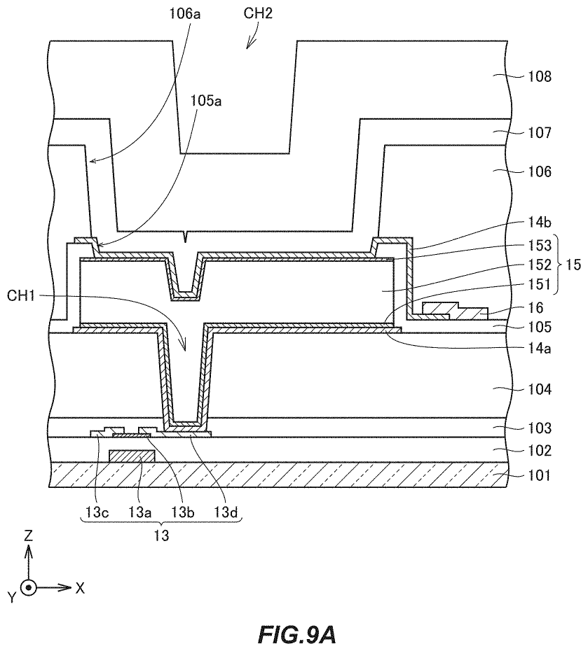

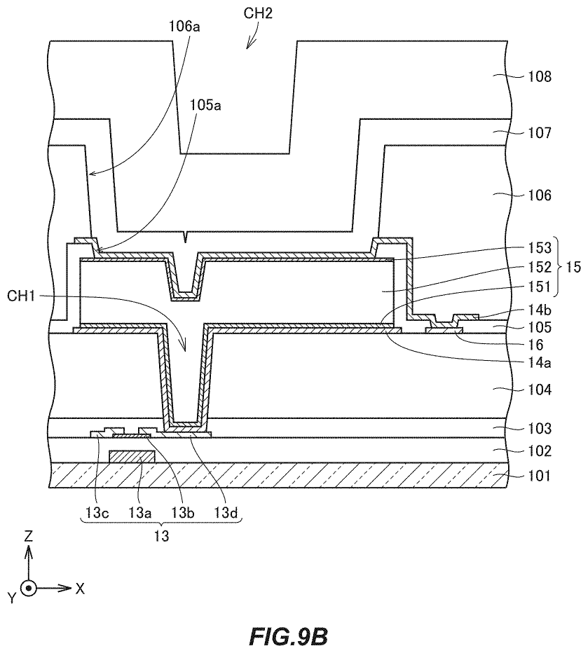

Embodiment 2 described above is described with reference to an example in which the upper electrode 14b is arranged above the bias line 16 so as to overlap with the bias line 16; the bias line 16, however, may be arranged above the upper electrode 14b so as to overlap with the upper electrode 14b, as illustrated in FIG. 9A.

In this case, after the upper electrode 14b is formed, the same steps as the above-described steps illustrated in FIGS. 6K and 6L are carried out in this order so that the bias line 16 overlapping with a part of the upper electrode 14b is formed on the third insulating film 105 outside the photoelectric conversion layer 15. After the bias line 16 is formed, the same steps as those in Embodiment 2 illustrated in FIGS. 8C to 8I are carried out.

### Application Example 2

Embodiment 2 described above is described with reference to an example in which the bias line 16 is provided on the third insulating film 105; the bias line 16, however, may be arranged on the second insulating film 104, as illustrated in FIG. 9B.

In this case, in the above-described steps illustrated in FIGS. 6E and 6F, the bias line 16 is formed simultaneously when the lower electrode 14a is formed. In other words, the lower electrode 14a and the bias line 16 are formed with a metal film obtained by laminating, for example, molybdenum nitride (MoN), aluminum (Al), and titanium (Ti) in this order. After the step illustrated in FIG. 6F, the same steps as those illustrated in FIGS. 6G to 6I and the same steps as those illustrated in FIGS. 8A to 8H are carried out, whereby the imaging panel illustrated in FIG. 9B is produced.

### Embodiment 3

The above-described embodiments are described with reference to an example in which the bias line 16 and the upper electrode 14b are connected at a position outside the contact hole CH2. The present embodiment is described with reference to an example in which the bias line 16 and the upper electrode 14b are connected in the contact hole CH2.

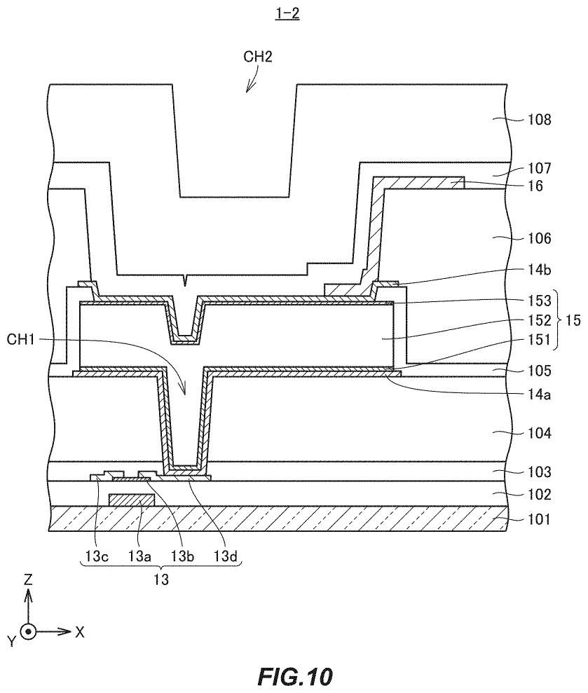

FIG. 10 is a schematic cross-sectional view illustrating a pixel in an imaging panel 1_2 in the present embodiment. In FIG. 10, the same configurations as those in Embodiment 1 are denoted by the same reference symbols as those in Embodiment 1.

As illustrated in FIG. 10, the bias line 16 in the present embodiment is in contact with the upper electrode 14b inside the contact hole CH2, and is arranged so as to extend from the upper electrode 14b to above the fourth insulating film 106.

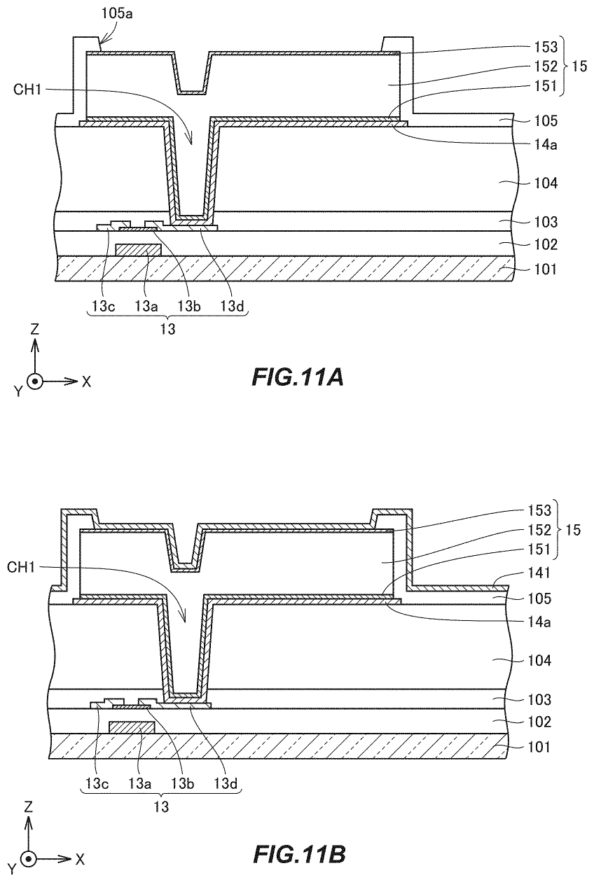

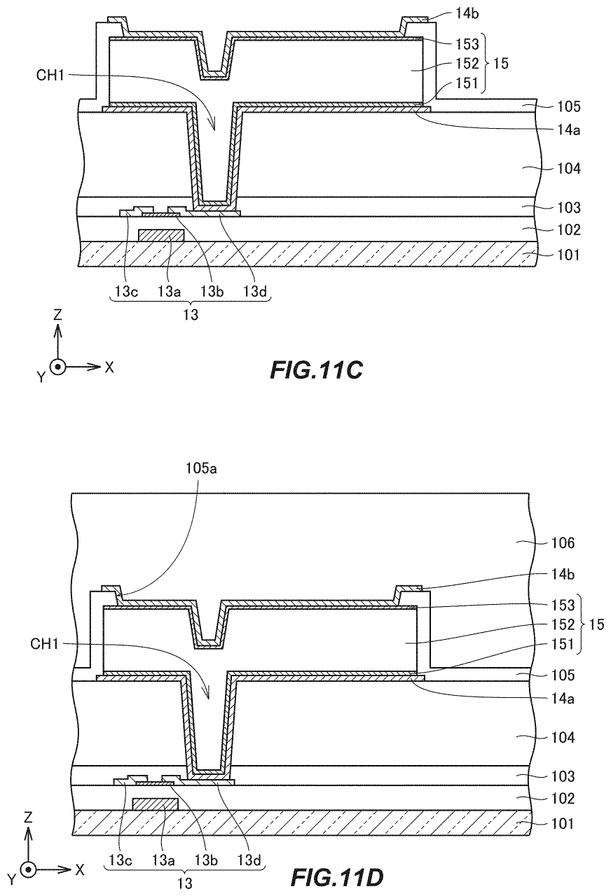

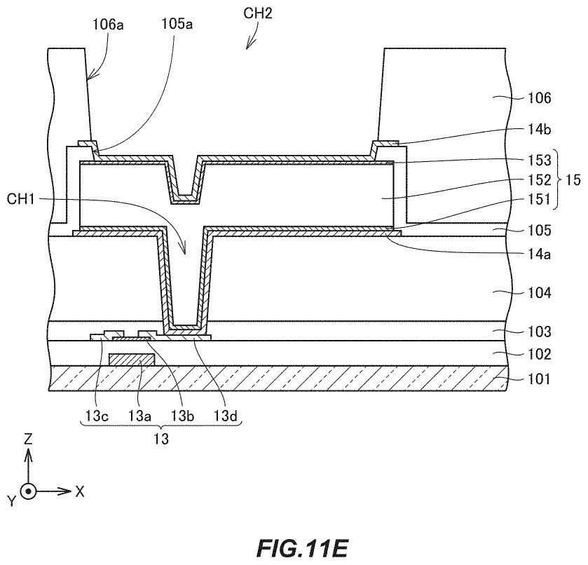

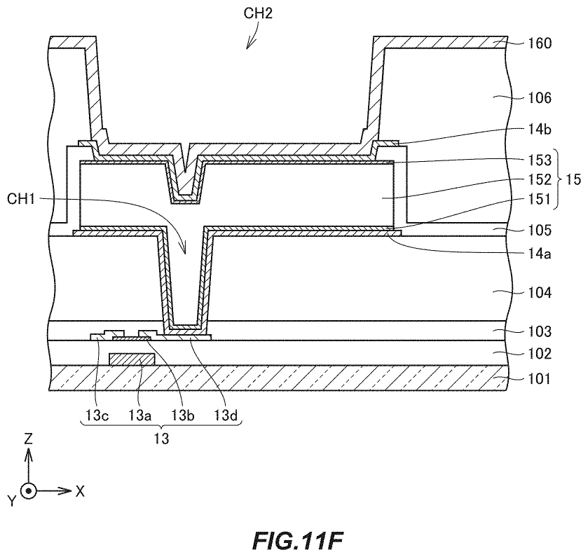

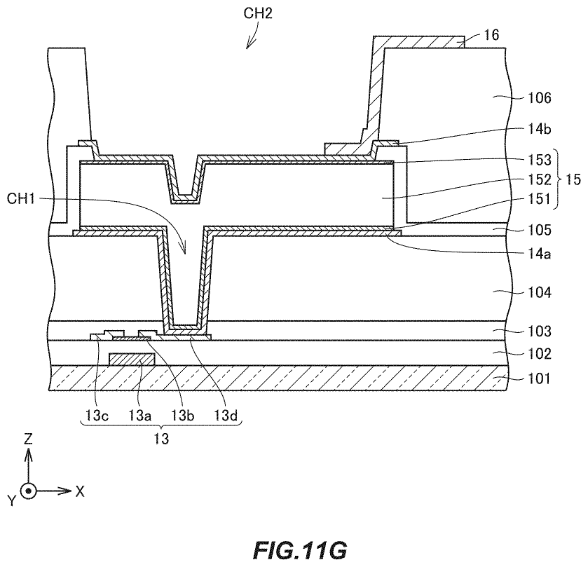

The process for producing the imaging panel 1_2 is as follows. First, the above-described steps illustrated in FIGS. 6A to 6I are carried out. Thereafter, the opening 105a of the third insulating film 105 is formed in the same manner as that in the step illustrated in FIG. 6N (see FIG. 11A).

Next, a transparent conductive film 141 is formed in the same manner as that in the step illustrated in FIG. 6O (see FIG. 11B), and the opening 105a is covered in the same manner as that in the step illustrated in FIG. 6P so that the upper electrode 14b overlapping with a part of the third insulating film 105 is formed (see FIG. 11C).

Thereafter, the fourth insulating film 106 is formed on the third insulating film 105 in the same manner as that in the step illustrated in FIG. 6J (see FIG. 11D), and the opening 104a of the fourth insulating film 106 is formed in the same manner as that in the step illustrated in FIG. 6M at a position overlapping with the opening 105a (see FIG. 11E). As a result, the contact hole CH2 composed of the openings 105a and 106a is formed.

Thereafter, a metal film 160 is formed on the fourth insulating film 106 and the upper electrode 14b in the same manner as that in the step illustrated in FIG. 6K (see FIG. 11F), and the metal film 160 is patterned in the same manner as that in the step illustrated in FIG. 6L (see FIG. 11G). As a result, the bias line 16 is formed so as to be in contact with a part of the upper electrode 14b and overlaps with a part of the fourth insulating film 106 in the contact hole CH2.

After the bias line 16 is formed, the same steps as those illustrated in FIGS. 6Q, 6R are carried out in this order, whereby the fifth insulating film 107 and the sixth insulating film 108 are formed in an upper layer with respect to the bias line 16 (see FIG. 10). In other words, in this example, the fifth insulating film 107 covers the bias line 16 and the upper electrode 14b, and the sixth insulating film 108 covers the fifth insulating film 107.

In Embodiment 3 described above, the bias line 16 and the upper electrode 14b are connected with each other inside the contact hole CH2. This causes the transmittance above the photoelectric conversion layer 15 to decrease, as compared with Embodiment 1. However, since the same step as that illustrated in FIG. 6H is performed in the present embodiment as well, the surface of the photoelectric conversion layer 15 is subjected to a cleaning treatment with use of hydrofluoric acid, and a reduction treatment with use of hydrogen plasma. Besides, side walls of the photoelectric conversion layer 15 are covered with the third insulating film 105 and the fourth insulating film 105 as the first protection films, and the fifth insulating film 107 and the sixth insulating film 108 as the second protection films, while the upper electrode 14b is covered with the fifth insulating film 107 and the sixth insulating film 108 as the second protection films. This therefore makes it possible to suppress the occurrence of off-leakage current caused by contamination with organic matters, naturally formed oxide films, and the like in the photoelectric conversion layer 15, in the present embodiment as well.

Incidentally, the configuration in which the bias line 16 and the upper electrode 14b are connected inside the contact hole CH2 is not limited to the above-described structure. The following description describes application examples of the present embodiment.

### Application Example 1

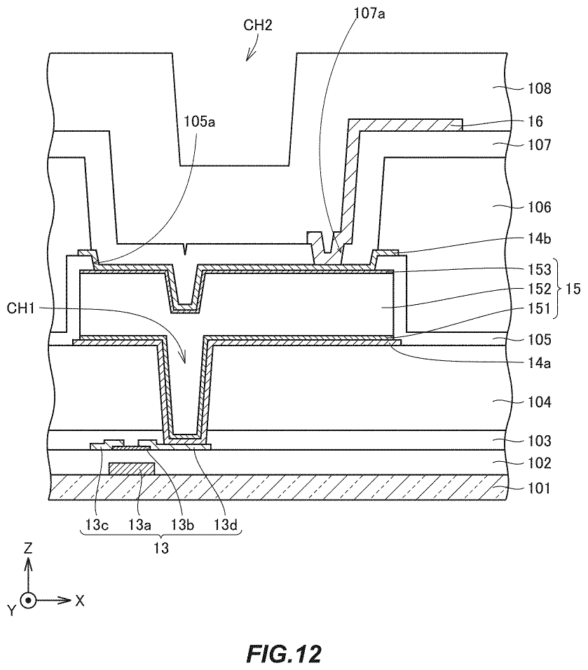

FIG. 12 is a cross-sectional view illustrating a structure of a pixel in an imaging panel according to Application Example 1 of Embodiment 3. As illustrated in FIG. 12, in Application Example 1, the fifth insulating film 107 has an opening 107a on an inner side with respect to the opening 105a of the third insulating film 105. The bias line 16 is provided above the fifth insulating film 107, and is in contact with the upper electrode 14b in the opening 107a.

In this case, after the step illustrated in FIG. 11E, the fifth insulating film 107 covering the fourth insulating film 106 and the upper electrode 14b is formed, and photolithography and wet etching are carried out so that the opening 107a of the fifth insulating film 107 is formed at a position overlapping with a part of the upper electrode 14b (not illustrated). Thereafter, the same steps as those illustrated in FIGS. 11F and 11G are carried out so that the bias line 16 that is in contact with the upper electrode 14b in the opening 107a and overlaps with a part of the fifth insulating film 107 is formed (see FIG. 12).

### Application Example 2

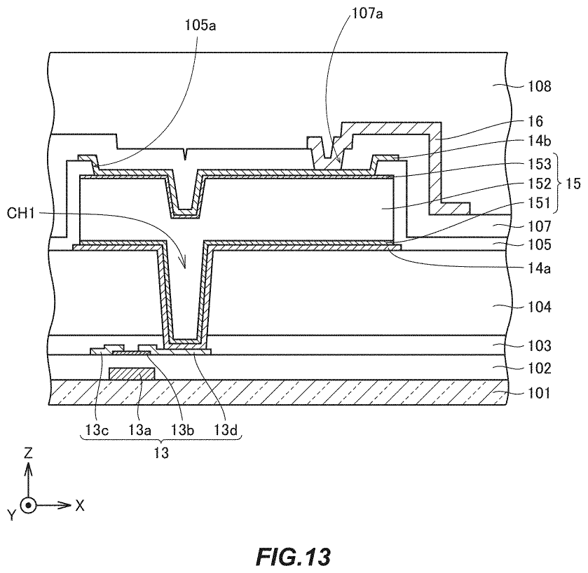

FIG. 13 is a cross-sectional view illustrating a structure of a pixel in an imaging panel according to Application Example 2 of Embodiment 3. As illustrated in FIG. 13, Application Example 2 is different from Application Example 1 described above in that the fourth insulating film 106 is not provided. The following description principally describes configurations different from those in Application Example 1 described above.

In Application Example 2, the fifth insulating film 107 is provided on the third insulating film 105 and the upper electrode 14b. In this case, therefore, after the above-described step illustrated in FIG. 11C, the fifth insulating film 107 covering the third insulating film 105 and the upper electrode 14b may be formed in the same manner as that in the step illustrated in FIG. 6Q, and the opening 107a of the fifth insulating film 107 may be formed at a position overlapping with a part of the upper electrode 14b. The configuration of Application Example 2 makes it possible to reduce the steps for producing the imaging panel, as compared with Application Example 1 described above.

### Embodiment 4

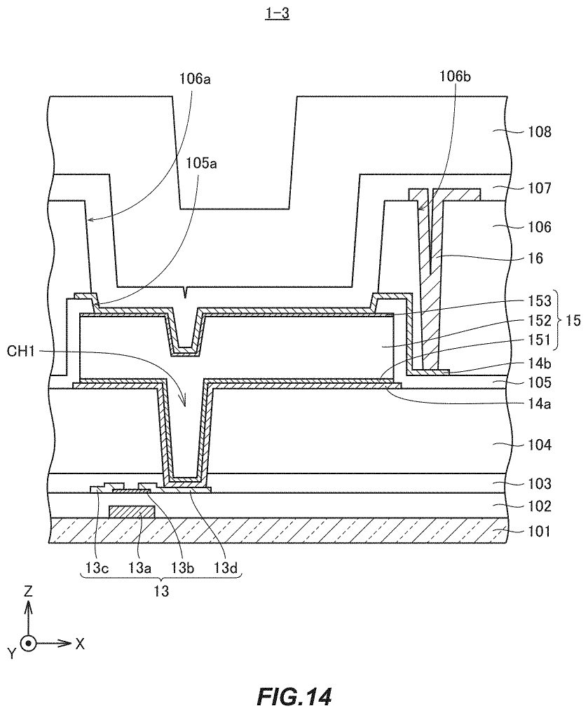

FIG. 14 is a schematic cross-sectional view illustrating a pixel in an imaging panel 1_3 according to the present embodiment. As illustrated in FIG. 14, the present embodiment is different from Embodiment 2 in that the bias line 16 is provided in an upper layer with respect to the third insulating film 105, and is different from Embodiment 3 in that the bias line 16 and the upper electrode 14b are connected outside the opening 105a. The following description principally describes configurations different from those in Embodiments 2 and 3.

As illustrated in FIG. 14, the position of an end in the X axis positive direction of the upper electrode 14b is arranged on an outer side with respect to the photoelectric conversion layer 15, as compared with an end thereof in the X axis negative direction so as to overlap with the third insulating film 106. In other words, the length over which the end on one side in the X axis direction of the upper electrode 14b overlaps with the third insulating film 106 is greater than the length over which the end on the other side of the upper electrode 14b overlaps with the third insulating film 106.

The fourth insulating film 106 has an opening 106a at a position that overlaps with the end on the X axis positive direction side of the upper electrode 14b. The bias line 16 is provided on the fourth insulating film 106 so as to be in contact with the upper electrode 14b in the opening layer 106a.

The process for producing the imaging panel 1_3 is as follows. First, the above-described steps illustrated in FIGS. 6A to 6I are carried out. Thereafter, the opening 105a of the third insulating film 105 and the upper electrode 14b are formed in the same manner as that in the above-described steps illustrated in FIGS. 11A to 11D. Then, the openings 106a and 106b of the fourth insulating film 106 are formed in the same manner as that in the above-described step illustrated in FIG. 11E.

Next, a metal film 160 that covers the fourth insulating film 106 and the upper electrode 14b is formed in the same manner as that in the above-described step illustrated in FIG. 11F, and the metal film 160 is patterned in the same manner as that in the step illustrated in FIG. 11G, whereby the bias line 16 is formed. Thereafter, the same steps as those illustrated in FIGS. 6Q and 6R are carried out in this order so that the upper electrode 14b in the opening 106a of the fourth insulating film 106 and fifth insulating film 107 covering the fourth insulating film 106 and the bias line 16 are formed, and subsequently, the sixth insulating film 108 covering the fifth insulating film 107 is formed (see FIG. 14)

### Application Example 1

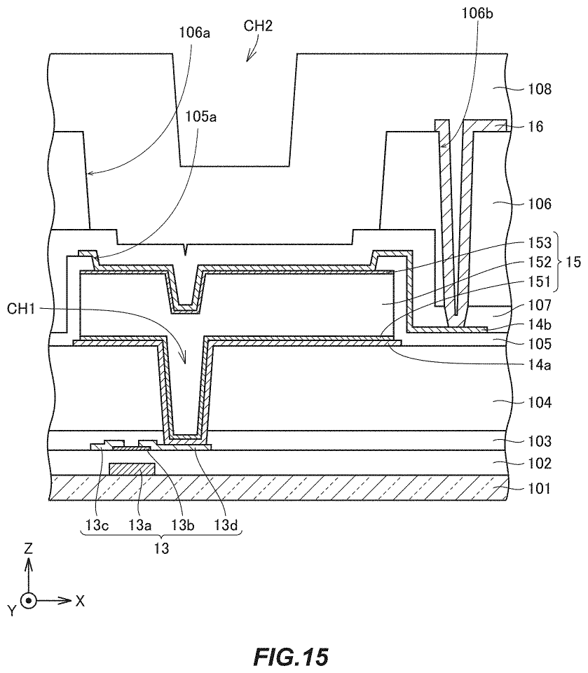

Embodiment 4 described above is described with reference to an example in which the fifth insulating film 107 overlaps on the fourth insulating film 106; the configuration, however, may be such that the fourth insulating film 106 overlaps on the fifth insulating film 107. FIG. 15 is a schematic cross-sectional view illustrating a pixel according to Application Example 1. The following description principally describes configurations different from those in Embodiment 4.

As illustrated in FIG. 15, the fifth insulating film 107 is provided on the third insulating film 105 so as to cover the upper electrode 14b in Application Example 1. Further, the fourth insulating film 106 is provided above the fifth insulating film 107. Above an end on the X axis positive direction side of the upper electrode 14b, a contact hole CH3 that passes through the fifth insulating film 107 and the fourth insulating film 106 is formed. The bias line 16 is provided on the fourth insulating film 106 so as to be in contact with the upper electrode 14b in the contact hole CH3.

In the present Application Example 1, as is the case with Embodiment 4, the upper electrode 14b is formed in the same manner as that in the above-described step illustrated in FIG. 11C. Thereafter, the fifth insulating film 107 covering the upper electrode 14b is formed on the third insulating film 105 in the same manner as that in the above-described step illustrated in FIG. 6Q. Next, photolithography and wet etching are carried out so that the opening 107a of the fifth insulating film 107 is formed at a position that overlaps with the X axis positive direction end of the upper electrode 14b.

Next, the fourth insulating film 106 is formed on the fifth insulating film 107 in the same manner as that in the above-described step illustrated in FIG. 11D, and the openings 106a and 106b of the fourth insulating film 106 are formed in the same manner as that in the above-described step illustrated in FIG. 11E. The opening 106a is provided above the opening 105a of the third insulating film 105, and the opening 106b is provided above the opening 107a of the fifth insulating film 107. The contact hole CH3 is formed with the openings 106b and 107a.

After the openings 106a and 106b of the fourth insulating film 106 are formed, the same steps as the above-described steps illustrated in FIGS. 11F and 11G are carried out in this order so that the bias line 16 that is in contact with the upper electrode 14b in the contact hole CH3 is formed on the fourth insulating film 106. Thereafter, the sixth insulating film 108 covering the fourth insulating film 106, the fifth insulating film 107, and the bias line 16 is formed in the same manner as that in the above-described step illustrated in FIG. 6R (see FIG. 15).

### Application Example 2

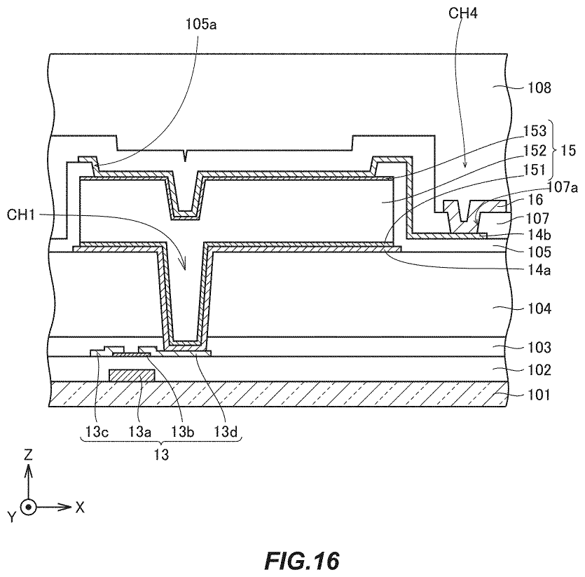

FIG. 16 is a schematic cross-sectional view illustrating a pixel according to Application Example 2. As illustrated in FIG. 16, Application Example 2 is different from Application Example 1 described above in that the fourth insulating film 106 is not provided.

In other words, in Application Example 2, the fifth insulating film 107 is provided on the upper electrode 14b. Besides, on the fifth insulating film 107, a contact hole CH4 formed with the opening 107a is provided at a position overlapping with the end on the X axis positive direction side of the upper electrode 14b. The bias line 16 is provided on the fifth insulating film 107 so as to be in contact with the upper electrode 14b in through the contact hole CH4. On the fifth insulating 107 and the upper electrode 16, the sixth insulating film 108 is provided.

In Application Example 2, the steps for forming the fourth insulating film 106 and the opening 106a of the fourth insulating film 106 in Application Example 1 described above are unnecessary. This makes it possible to reduce the number of steps for producing an imaging panel, as compared with Application Example 1.

The embodiments of the present invention are described as above, but the above-described embodiments are merely examples for implementing the present invention. The present invention, therefore, is not limited to the above-described embodiments, but can be appropriately modified without deviating from the scope of the invention and be implemented. The following description describes modifications of the present invention.

(1) In Application Examples 1, 2 of Embodiment 3 and Application Examples 1, 2 of Embodiment 4 described above, a cap layer that covers a surface of the bias line 16 and has conductivity may be provided. The cap layer may be, for example, a metal film containing titanium (Ti), or a transparent conductive film made of ITO or the like.

In an upper layer with respect to the bias line 16 in Application Examples 1, 2 of Embodiment 3 and Application Examples 1, 2 of Embodiment 4 described above, only one insulating layer (the sixth insulating film 108) is provided. Therefore, in a case where no cap layer is provided, it is more likely that the bias line 16 would be corroded as compared with a case where two or more insulating layers are provided in an upper layer with respect to the bias line 16. By providing a cap layer as in the present modification example, the corrosion of the bias line 16 can be prevented, even if only one insulating layer is provided so as to cover the bias line 16.

### DESCRIPTION OF REFERENCE NUMERALS

1, 1_1 to 1_3: imaging panel
1A: scintillator
2: control unit
2A: gate control unit
2B: signal reading unit
3: X-ray source
10: source line
11: gate line
12: photodiode
13: thin film transistor (TFT)
13a: gate electrode
13b: semiconductor active layer
13c: source electrode
13d: drain electrode
14a: lower electrode
14b: upper electrode
15: photoelectric conversion layer
16: bias line
100: X-ray imaging device
101: substrate
102: gate insulating film
103: first insulating film
104: second insulating film
105: third insulating film
106: fourth insulating film
107: fifth insulating film
108: sixth insulating film
151: n-type amorphous semiconductor layer
152: intrinsic amorphous semiconductor layer
153: p-type amorphous semiconductor layer

1: An imaging panel that generates an image based on scintillation light that is obtained from X-rays transmitted through an object, the imaging panel comprising:
a photoelectric conversion layer;
a first electrode provided on a side irradiated with the X-rays, the first electrode and a second electrode forming a pair; and
a first protection layer,
wherein the first protection layer covers a side surface of the photoelectric conversion layer, and overlaps with the photoelectric conversion layer on the X-ray irradiated side so as to have an opening on an inner side with respect to an end of the photoelectric conversion layer, and
the first electrode is arranged so as to be in contact with the photoelectric conversion layer in the opening, and to overlap with at least a part of the first protection layer.

2: The imaging panel according to claim 1,
wherein the photoelectric conversion layer includes:
a first amorphous semiconductor layer that has a first conductivity;
an intrinsic amorphous semiconductor layer that is in contact with the first amorphous semiconductor layer; and
a second amorphous semiconductor layer that is in contact with the intrinsic amorphous semiconductor layer, and has a second conductivity that is opposite to the first conductivity,
the first protection layer has the opening on a top surface of the second amorphous semiconductor layer,
the first electrode is in contact with of the second amorphous semiconductor layer in the opening, and
a portion of the second amorphous semiconductor layer in an area where the opening is provided has a smaller thickness than that of a portion of the second amorphous semiconductor layer in an area that overlaps with the first protection layer.

3: The imaging panel according to claim 1,
wherein the first protection layer includes a first inorganic insulating film and a first organic insulating film, and
the first organic insulating film is arranged so as to overlap on the first inorganic insulating film.

4: The imaging panel according to claim 1,
wherein the first protection layer includes a first inorganic insulating film and a first organic insulating film,
the first electrode is arranged so as to overlap on the first inorganic insulating film, and
the first organic insulating film is provided in an upper layer with respect to the first electrode, and has an opening on an inner side with respect to the end of the photoelectric conversion layer and on an outer side with respect to the opening of the first inorganic insulating film.

5: The imaging panel according to claim 1,
wherein the first protection layer includes a first inorganic insulating film, and
the first electrode is arranged so as to overlap on the first inorganic insulating film.

6: The imaging panel according to claim 1, further comprising:
a second protection layer that is arranged so as to overlap with the first electrode and at least a part of the first protection layer.

7: The imaging panel according to claim 6,
wherein the second protection layer includes a second inorganic insulating film and a second organic insulating film,
the second inorganic insulating film is in contact with the first electrode, and
the second organic insulating film is provided on the second inorganic insulating film.

8: The imaging panel according to claim 6,
wherein the second protection layer includes a second inorganic insulating film and a second organic insulating film, and
the second inorganic insulating film is in contact with the first electrode, and is arranged between the first inorganic insulating film and the second organic insulating film outside the opening.

9: The imaging panel according to claim 1, further comprising:
a bias line that is in contact with the first electrode, and to which a predetermined bias voltage is applied.

10: The imaging panel according to claim 9,
wherein the bias line is in contact with the first electrode outside the opening.

11: The imaging panel according to claim 9,
wherein the bias line is provided in an upper layer with respect to the first protection layer.

12: The imaging panel according to claim 9, further comprising:
a conductive film that covers the bias line.

13: The imaging panel according to claim 1,
wherein the opening has an area at a ratio of 70.56% or more with respect to an area on the X-ray irradiated side of the photoelectric conversion layer.

14: A method for producing an imaging panel that generates an image based on scintillation light that is obtained from X-rays transmitted through an object, the producing method comprising the steps of:
sequentially forming a first amorphous semiconductor layer having a first conductivity, an intrinsic amorphous semiconductor layer, and a second amorphous semiconductor layer having a second conductivity that is opposite to the first conductivity, on a substrate;
forming a photoelectric conversion layer by etching the first amorphous semiconductor layer, the intrinsic amorphous semiconductor layer, and the second amorphous semiconductor layer;
carrying out a removal treatment for removing matters that adhere to a surface of the photoelectric conversion layer;
forming a first protection layer after the removal treatment, the first protection layer covering a side surface of the photoelectric conversion layer, and overlapping with a part of the photoelectric conversion layer on the X-ray irradiated side so as to have an opening on an inner side with respect to an end of the photoelectric conversion layer; and
forming a first electrode arranged so as to be in contact with the photoelectric conversion layer in the opening and to overlap with at least a part of the first protection layer, the first electrode and a second electrode forming a pair.

15: The imaging panel producing method according to claim 14,
wherein the removal treatment includes a cleaning treatment with use of hydrofluoric acid.

16: The imaging panel producing method according to claim 14,
wherein the opening in the first protection layer is formed by performing wet etching with use of hydrofluoric acid to the first protection layer.

17: The imaging panel producing method according to claim 12,
wherein the opening has an area at a ratio of 70.56% or more with respect to an area on the X-ray irradiated side of the photoelectric conversion layer.
